(19) United States
(12) Patent Application Publication
(10) Pub. No.: US 2025/0374653 A1
(43) Pub. Date: Dec. 4, 2025

(54) ISOLATION STRUCTURE FOR NANOSTRUCTURE DEVICE AND METHODS OF FORMING THE SAME

(71) Applicant: Taiwan Semiconductor Manufacturing Co., Ltd., Hsinchu (TW)

(72) Inventors: Tzu-Ging Lin, Kaohsiung City (TW); Chun-Liang Lai, Hsinchu (TW); Jun-Ye Liu, Hsinchu (TW); Yen Ju Chen, Hsinchu (TW); Jih-Jse Lin, Sijhih City (TW); Chih-Ming Sun, New Taipei City (TW); Yun-Chen Wu, Hsinchu (TW)

(21) Appl. No.: 18/820,597

(22) Filed: Aug. 30, 2024

Related U.S. Application Data
(60) Provisional application No. 63/655,674, filed on Jun. 4, 2024.

(51) Int. Cl. H01L 21/8234; H01L 27/088; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 64/017; H10D 84/0128; H10D 84/0151; H10D 84/83

(57) ABSTRACT

A method includes forming a fin over a substrate; forming a first isolation region over the substrate; forming a hard mask over the first isolation region, wherein the fin protrudes from the hard mask; forming dummy nanostructures over the fin; removing the dummy nanostructures; removing a portion of the fin to form an opening extending through the hard mask and the first isolation region; forming a second isolation region over the hard mask and in the opening; and forming a gate structure along a sidewall of the second isolation region.

### PRIORITY CLAIM AND CROSS-REFERENCE

This application claims the benefit of U.S. Provisional Application No. 63/655,674, filed on Jun. 4, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3, 4, 5, 6, 7, 8A, 8B, 8C, 9A, 9B, 9C, 10A, 10B, 10C, 11A, 11B, 11C, 11D, 12A, 12B, 13A, 13B, 14A, 14B, 15A, 15B, 16A, 16B, 17A, 17B, 17C, 17D, 17E, 18A, 18B, 18C, 18D, 19A, 19B, 19C, 19D, 20A, 20B, 20C, 21A. 21B, 21C, 22A, 22B, 22C, 23A, 23B, 23C, 24A, 24B, 24C, 25A, 25B, 25C, 26A, 26B, 26C, 27A, 27B, 27C, 28A, 28B, 28C, 29A, 29B, 29C, 30, 31A, 31B, 31C, and 31D illustrate cross-sectional views of intermediate stages in the manufacturing of nanostructure-FETs, in accordance with some embodiments.

FIGS. 32A and 32B illustrate cross-sectional views of intermediate stages in the manufacturing of transistor isolation structures, in accordance with some embodiments.

FIGS. 33A and 33B illustrate cross-sectional views of intermediate stages in the manufacturing of transistor isolation structures, in accordance with some embodiments.

FIGS. 34A and 34B illustrate cross-sectional views of intermediate stages in the manufacturing of transistor isolation structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nanostructure field-effect transistors (e.g., “nanostructure-FETs” or “nano-FETs”). Various embodiments may be applied, however, to dies comprising other types of transistors (e.g., fin field-effect transistors (FinFETs), planar transistors, stacking transistors, or the like) in lieu of or in combination with the nanostructure-FETs.

According to various embodiments, oxide dummy regions are used to fill regions between channel regions of a nanostructure-FET where the gate structures are subsequently formed. The use of oxide dummy regions allows for more selective etches to be used when removing the oxide dummy regions, which can reduce the risk of etch damage to the channel regions or the source/drain regions. A hard mask is formed over isolation regions that surround the channel regions that protects the isolation regions from undesired etching. For example, the hard mask can protect the isolation regions from etching when the oxide dummy regions are removed during formation of transistor isolation structures. The use of various selective etches can also reduce undesired etching of the isolation regions.

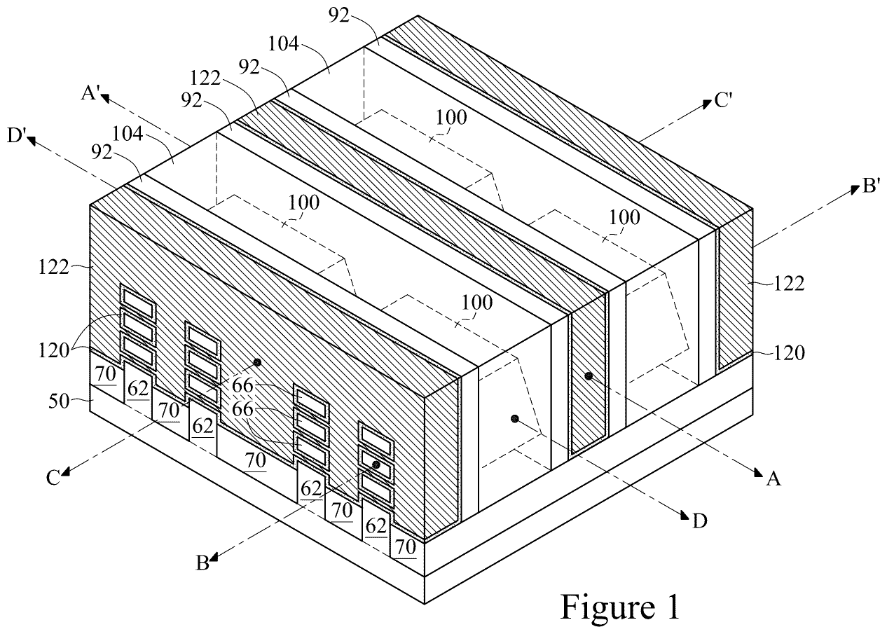

FIG. 1 illustrates an example of nanostructure-FETs (e.g., nanowire FETs, nanosheet FETs, nano-FETs, or the like), gate-all-around (GAA) FETs, or the like) in a three-dimensional view, in accordance with some embodiments. Some features of the nanostructure-FETs may be simplified and/or omitted in FIG. 1 for clarity. The nanostructure-FETs comprise nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. The nanostructures 66 may include p-type nanostructures, n-type nanostructures, or a combination thereof. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Some portions of the isolation regions 70 may be covered by a protective layer, hard mask, or the like (not illustrated in FIG. 1). Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portions of the fins 62 and/or the substrate 50 may comprise a single material or a plurality of materials. In this context, the fins 62 refer to the portion extending between the neighboring isolation regions 70.

The gate dielectric layers 120 are over top surfaces of the fins 62 and along top surfaces, sidewalls, and bottom surfaces of the nanostructures 66. Gate electrodes 122 are over the gate dielectric layers 120. The gate dielectric layers 120 and gate electrodes 122 may be collectively be called “gate structures” or “gate stacks.” Source/drain regions 100 (e.g., epitaxial source/drain regions 100) are disposed on the fins 62 at opposing sides of the gate dielectric layers 120 and the gate electrodes 122. Source/drain region(s) 100 may refer to a source or a drain, individually or collectively dependent upon the context. An inter-layer dielectric (ILD) 104 is formed over the source/drain regions 100. Contacts (subsequently described) to the source/drain regions 100 will be formed through the ILD 104. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ extends along a longitudinal axis of a gate electrode 122. Cross-section B-B′ is perpendicular to cross-section A-A′ and extends along a longitudinal axis of a fin 62 of a nanostructure-FET and in a direction of, for example, a current flow between the source/drain regions 100 of the nanostructure-FET. Cross-section C-C′ is parallel to cross-section B-B′ (e.g., is perpendicular to cross-section A-A′) and extends between adjacent fins 62 of the nanostructure-FETs and between the corresponding adjacent source/drain regions 100 of the nanostructure-FETs. Cross-section D-D′ is parallel to cross-section A-A′ and extends through source/drain regions 100 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs. Other FETs or configurations of FETs are possible.

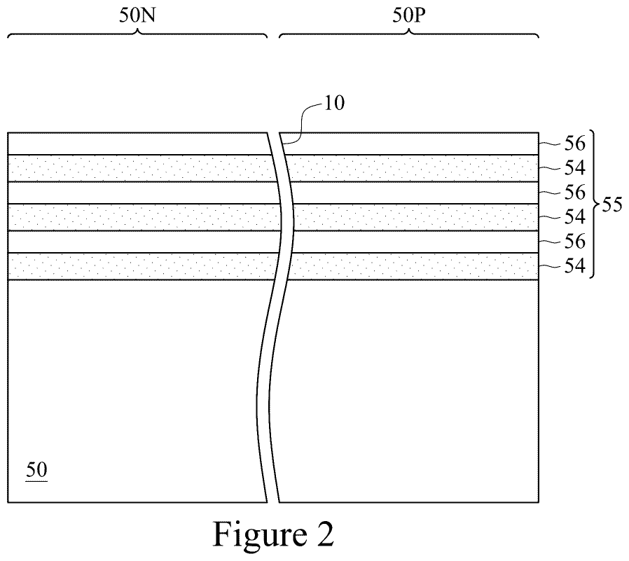

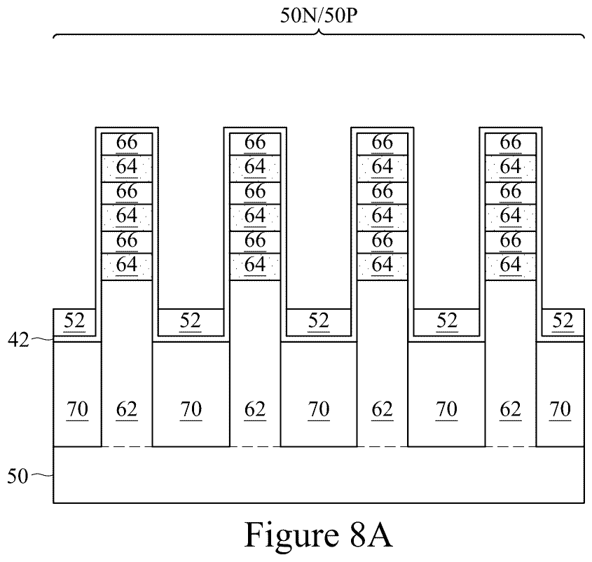

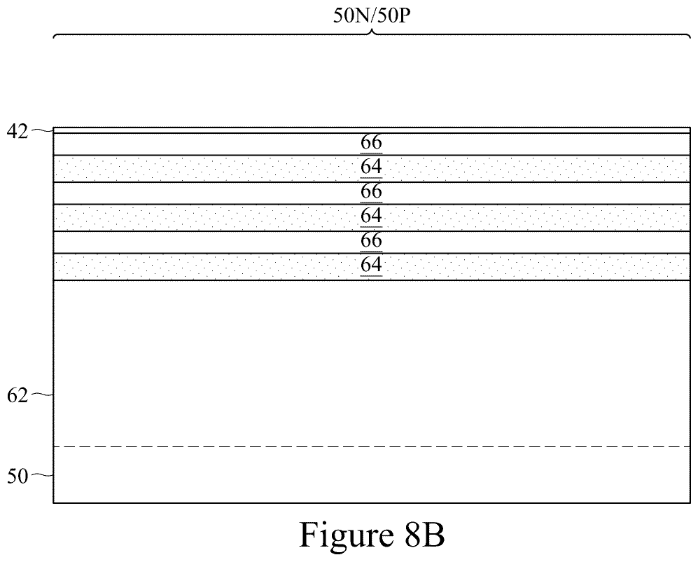

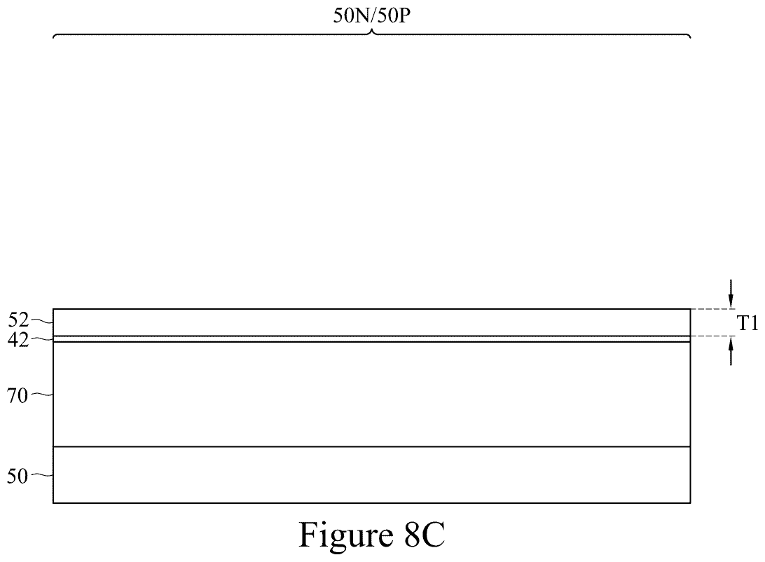

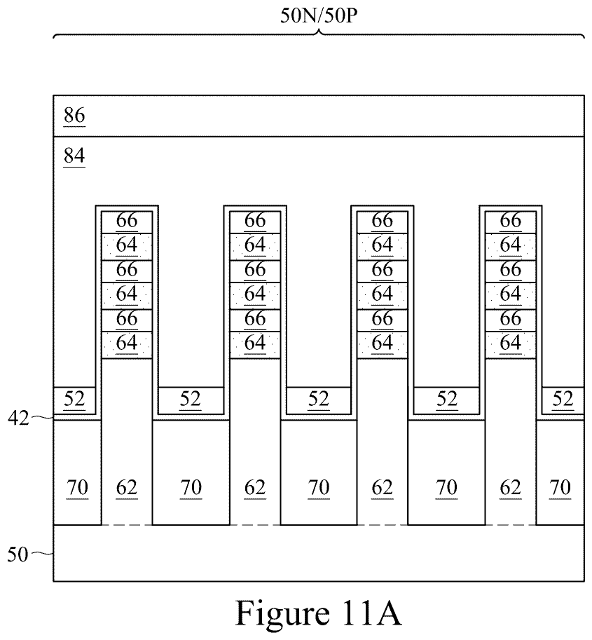

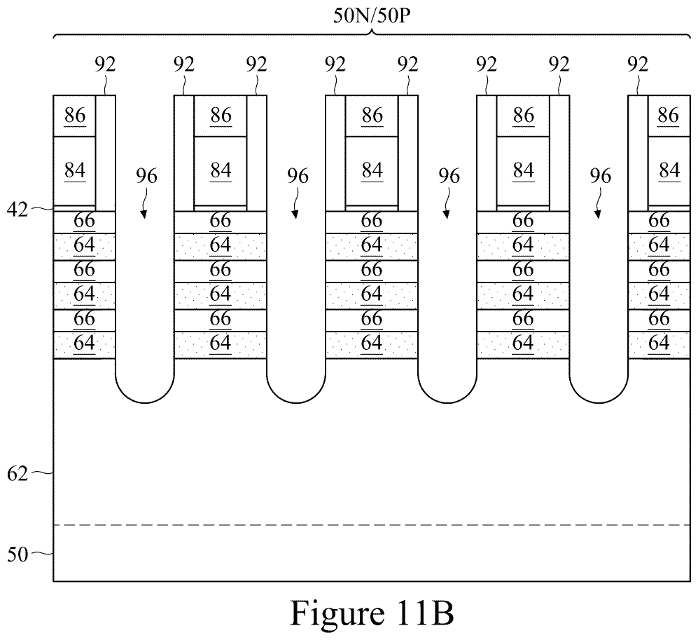

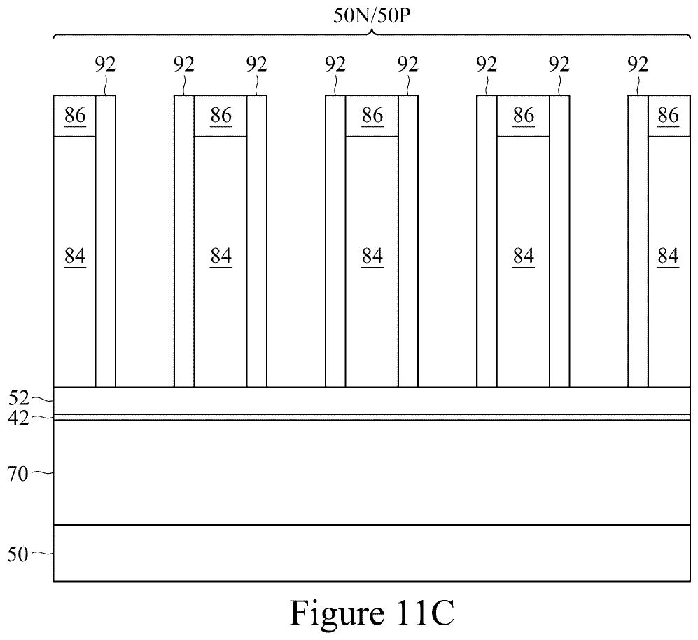

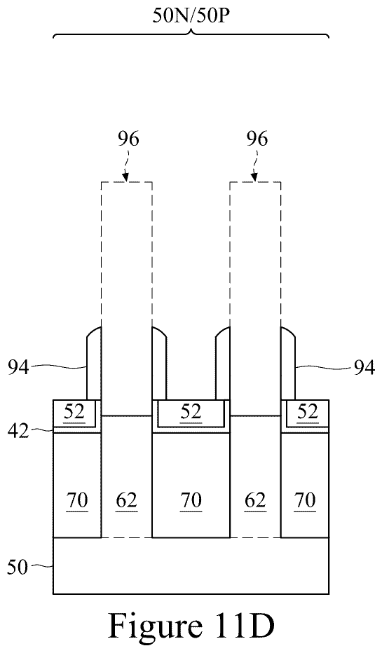

FIGS. 2-31C are views of intermediate stages in the manufacturing of nanostructure-FETs, in accordance with some embodiments. FIGS. 2, 3, 4, 5, 6, 7, 8A, 9A, 10A, 11A, 12A, 13A, 14A, 15A, 17A, 18A, 19A, 20A, 21A, 22A, 23A, 24A, 25A, 26A, 27A, 28A, 29A, and 31A illustrate cross-sectional views along a similar cross-section as reference cross-section A-A′ in FIG. 1. FIGS. 8B, 9B, 10B, 11B, 12B, 13B, 14B, 15B, 16A, 16B, 17B, 18B, 19B, 20B, 21B, 22B, 23B, 24B, 25B, 26B, 27B, 28B, 29B, 30, and 31B illustrate cross-sectional views along a similar cross-section as reference cross-section B-B′ in FIG. 1. FIGS. 8C, 9C, 10C, 11C, 17C, 18C, 19C, 20C, 21C, 22C, 23C, 24C, 25C, 26C, 27C, 28C, 29C, and 31C illustrate cross-sectional views along a similar cross-section as reference cross-section C-C′ in FIG. 1. FIGS. 11D, 17D, 17E, 18D, 19D, and 31D illustrate cross-sectional views along a similar cross-section as reference cross-section D-D′ in FIG. 1.

In FIG. 2, a substrate 50 is provided, in accordance with some embodiments. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 55 is formed over the substrate 50, in accordance with some embodiments. The multi-layer stack 55 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 are patterned to form channel regions for nanostructure-FETs in one region (e.g., the p-type region 50P), and the second semiconductor layers 56 are patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 55 is illustrated as including three of the first semiconductor layers 54 and three of the second semiconductor layers 56. It should be appreciated that the multi-layer stack 55 may include any number of the first semiconductor layers 54 and the second semiconductor layers 56. Each of the layers of the multi-layer stack 55 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 55 are formed to be thinner than other layers of the multi-layer stack 55. For example, in other embodiments, the bottom-most second semiconductor layer 56 (e.g., the second semiconductor layer 56 closest to the substrate 50) may be thinner than overlying second semiconductor layers 56 to improve short channel control in the resulting nanostructure-FETs. Other combinations or variations of layer thicknesses are possible.

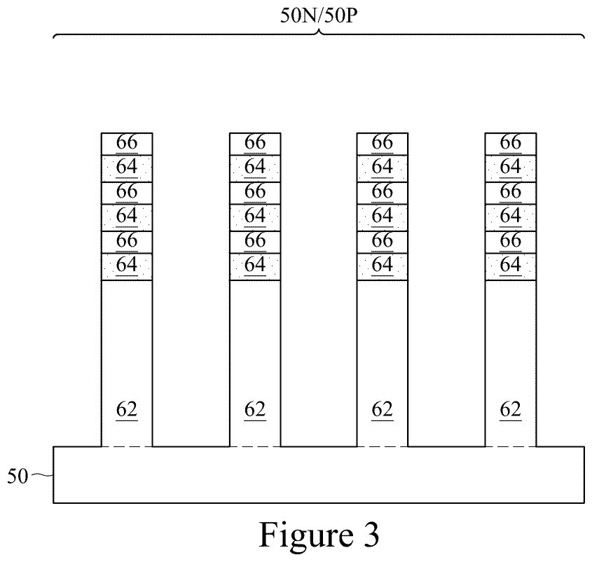

In FIG. 3, fins 62 are formed in the substrate 50, and first nanostructures 64 and second nanostructures 66 are formed in the multi-layer stack 55, in accordance with some embodiments. The first nanostructures 64 and the second nanostructures 66 may be collectively referred to as the nanostructures 64/66 herein. In some cases, the nanostructures 64/66 over a fin 62 may be considered a nanostructure stack or the like. FIG. 3 may be in either of the n-type region 50N or the p-type region 50P of the substrate 50 unless specifically discussed.

In some embodiments, the nanostructures 64/66 and the fins 62 may be formed in the multi-layer stack 55 and the substrate 50, respectively, by etching trenches in the multi-layer stack 55 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 55 may further define first nanostructures 64 from the first semiconductor layers 54 and define second nanostructures 66 from the second semiconductor layers 56.

The fins 62 and the nanostructures 64/66 may be patterned using any suitable methods. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66. Other patterning techniques are possible.

The fins 62 are illustrated as having substantially equal widths in both the n-type region 50N and the p-type region 50P. In other embodiments, a width of the fins 62 in the n-type region 50N may be greater or less than a width of the fins 62 in the p-type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

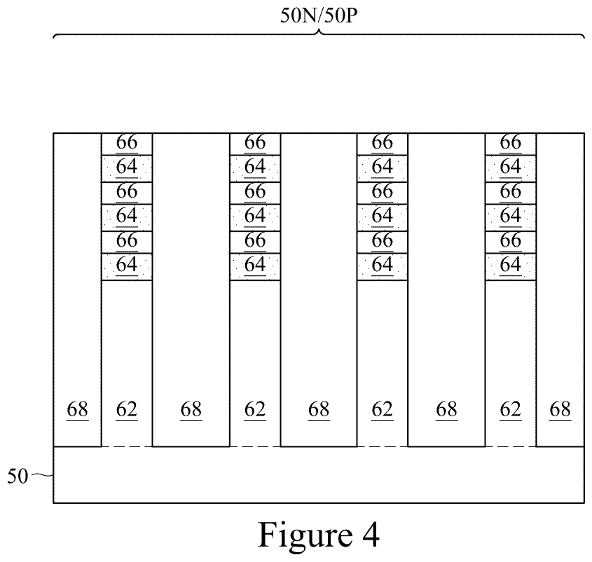

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials, may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, a combination thereof, or the like may be utilized. The planarization process may expose the nanostructures 64/66 such that top surfaces of the nanostructures 64/66 and the insulation material 68 are substantially level or coplanar after the planarization process is complete.

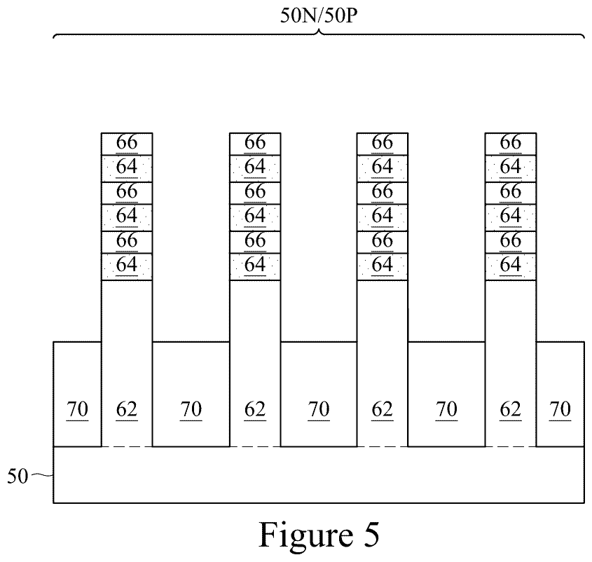

In FIG. 5, the insulation material 68 is recessed to form Shallow Trench Isolation (STI) regions 70, in accordance with some embodiments. The STI regions 70 are adjacent to the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. In some cases, portions of the fins 62 and/or the nanostructures 64/66 may be below a top surface of the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using dilute hydrofluoric acid (“dHF”) or the like may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further in FIG. 5, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may include phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

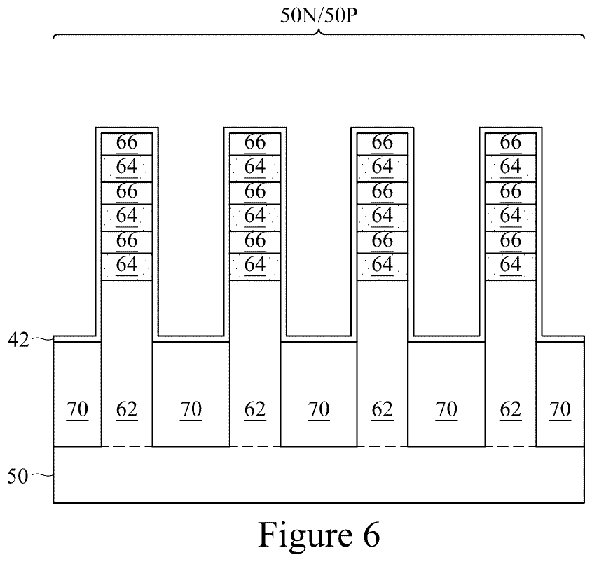

In FIG. 6, a dielectric liner 42 is formed over the STI regions 70, the fins 62, and the nanostructures 64/66, in accordance with some embodiments. The dielectric liner 42 may be formed as a conformal layer over and along sidewalls of the fins 62 and nanostructures 64/66. The dielectric liner 42 may be formed to protect surfaces of the STI regions 70, the fins 62, and/or the nanostructures 64/66 from etching during subsequent processes, and to act as an etch stop layer in some subsequent processes. In some embodiments, portions of the dielectric liner 42 may be subsequently utilized as a dummy dielectric layer, a dummy gate dielectric, or the like. The dielectric liner 42 may comprise a silicon-based dielectric material, such as silicon oxide, silicon oxynitride, or the like. Other materials are possible. The dielectric liner 42 may be deposited or thermally grown according to acceptable techniques.

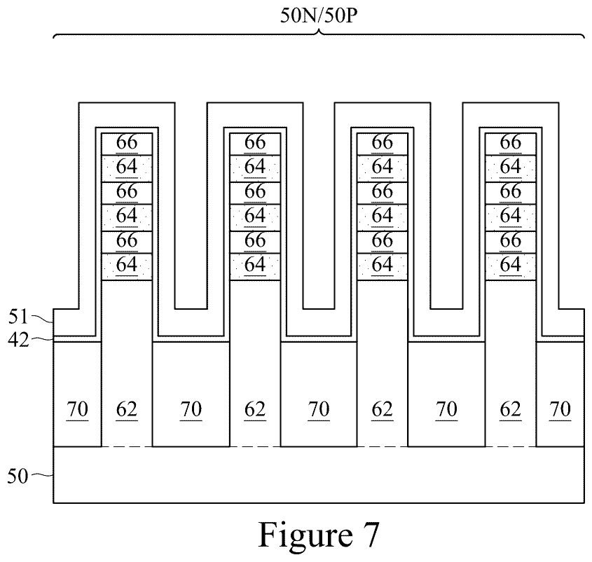

In FIG. 7, a hard mask layer 51 is deposited over the dielectric liner 42, in accordance with some embodiments. The hard mask layer 51 subsequently forms a hard mask 52 that protects some surfaces of the STI regions 70 from etching during subsequent processes. Accordingly, the hard mask 52 may be considered a protective layer or the like. The hard mask layer 51 is deposited over the STI regions 70 and over and along sidewalls of the fins 62 and/or the nanostructures 64/66. Accordingly, the hard mask layer 51 may be deposited as a continuous layer, in some cases. The hard mask layer 51 may comprise one or more materials that have a high etching selectivity from the etching of the materials of the dielectric liner 42, the STI regions 70, the fins 62, and/or the nanostructures 64/66. In some embodiments, the hard mask layer 51 may comprise a nitride, such as silicon nitride, silicon oxynitride, silicon carbide, silicon carbonitride, silicon oxycarbonitride, or the like. In other embodiments, the hard mask layer 51 comprises an oxide, such as hafnium oxide, zirconium oxide, or the like. Other materials are possible, and the hard mask layer 51 may comprise multiple layers of different materials, in some cases. The hard mask layer 51 may be deposited using a suitable process, such as CVD, plasma-enhanced CVD (PECVD), ALD, or the like. The deposition process may be conformal. In some cases, portions of the hard mask layer 51 deposited on sidewall surfaces (e.g., vertical surfaces) may be thinner than portions of the hard mask layer 51 deposited on lateral surfaces (e.g., top surfaces).

In FIGS. 8A-8C, upper portions of the hard mask layer 51 are removed to form the hard mask 52, in accordance with some embodiments. The upper portions of the hard mask layer 51 may include portions along sidewalls of the fins 62, portions along sidewalls of the nanostructure 64/66, and/or portions over top surfaces of the nanostructures 64/66. As shown in FIG. 8A, the remaining portions of the hard mask layer 51 over top surfaces of the STI regions 70 form the hard mask 52. The upper portions of the hard mask layer 51 may be removed using one or more acceptable etch processes, such as a dry etch, a wet etch, or a combination thereof. The etch process may be anisotropic. In some cases, the etch process may thin lateral portions of the hard mask layer 51 that form the hard mask 52. As shown in FIG. 8A, the dielectric liner 42 is between the hard mask 52 and the STI regions 70. Further, top surfaces of the hard mask 52 may have a flat surface as illustrated, a convex surface, a concave surface (such as dishing), or a combination thereof. In some embodiments, the hard mask 52 has a thickness T1 that is in the range of about 5 nm to about 20 nm, though other thicknesses are possible. In some cases, a thicker T1 can result in decreased parasitic capacitance. In some cases, the thickness T1 may be controlled such that the stress imparted by the hard mask 52 is similar to the stress imparted by the isolation regions 70.

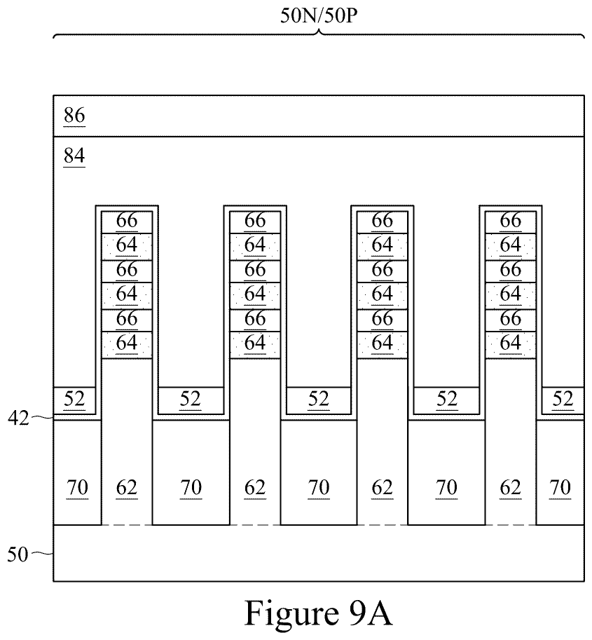

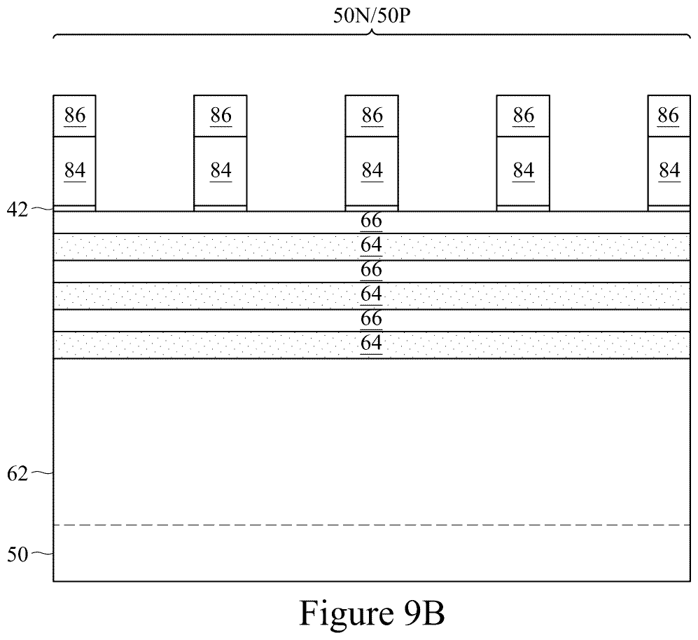

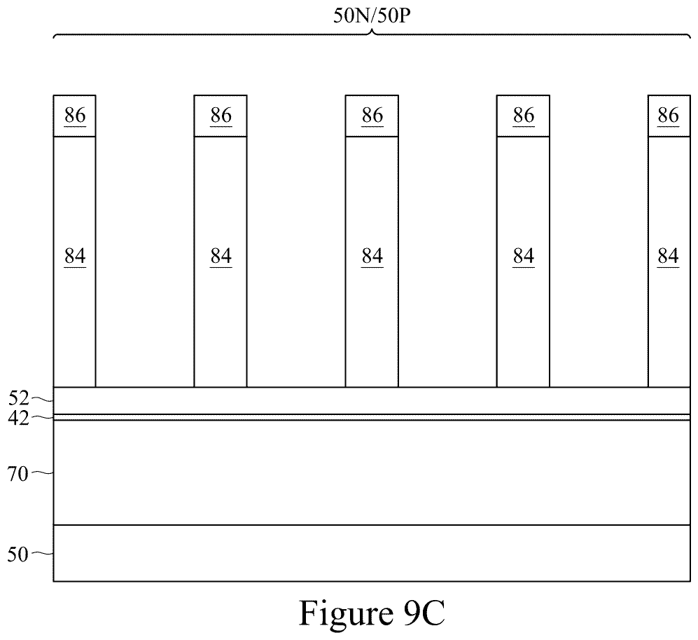

In FIGS. 9A-9C, dummy gates 84 and masks 86 are formed over the hard mask 52 and the dielectric liner 42, in accordance with some embodiments. In some embodiments, a dummy gate layer is formed over the hard mask 52 and nanostructures 64/66, and along sidewalls of the fins 62 and nanostructures 64/66. A mask layer is formed over the dummy gate layer. The dummy gate layer may be deposited over the dummy dielectric layer and then planarized, such as by a CMP process or the like. The dummy gate layer may be formed of a conductive or non-conductive material and may be selected from a group including amorphous silicon, polycrystalline-silicon (polysilicon), polycrystalline silicon germanium (poly-SiGe), metallic nitrides, metallic silicides, metallic oxides, and metals. The material of the dummy gate layer may be deposited by CVD, physical vapor deposition (PVD), sputter deposition, or another suitable technique. The dummy gate layer may be formed of other materials that have a high etching selectivity from the etching of insulation materials, e.g., hard mask 52, the dielectric liner 42, and/or the STI regions 70. The dummy gate layer may be formed of multiple layers of different materials, in some cases. The mask layer may be deposited over the dummy gate layer. The mask layer may be formed of a dielectric material such as silicon nitride, silicon oxynitride, silicon oxide, or the like. The mask layer may be formed of multiple layers of different materials, in some cases.

Subsequently, the mask layer is patterned using acceptable photolithography and etching techniques to form masks 86. The pattern of the masks 86 then may be transferred to the dummy gate layer form dummy gates 84. In some embodiments, the pattern of the masks 86 is also transferred to the dielectric liner 42, with portions of the dielectric liner 42 on the fins 62 and/or the nanostructures 64/66 forming dummy gate dielectrics. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise (e.g., longitudinal) direction of respective fins 62. The masks 86 can optionally be removed after patterning, such as by any acceptable etching technique. In this example, a single dummy gate layer and a single mask layer are formed across the n-type region 50N and the p-type region 50P.

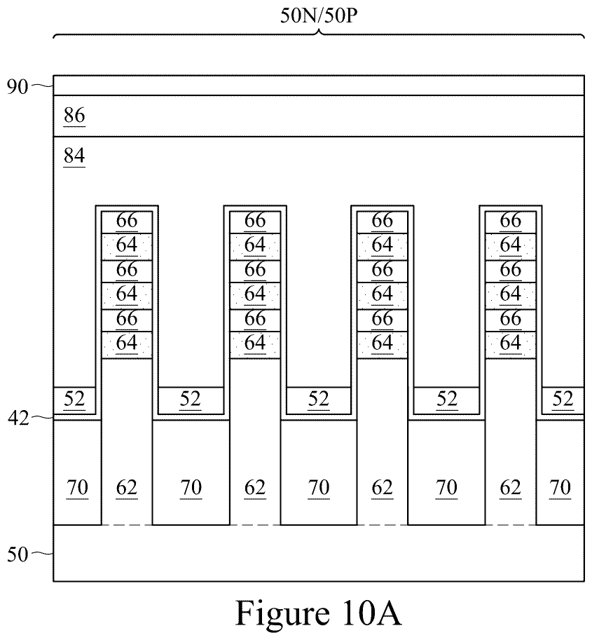

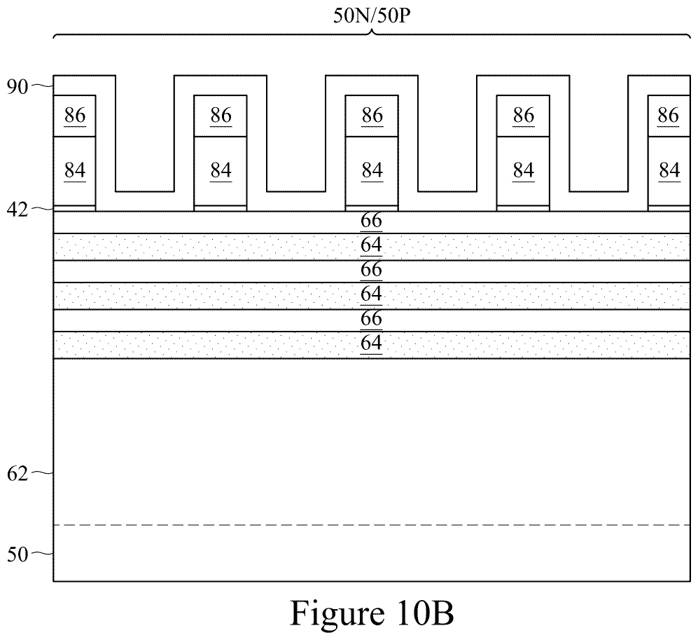

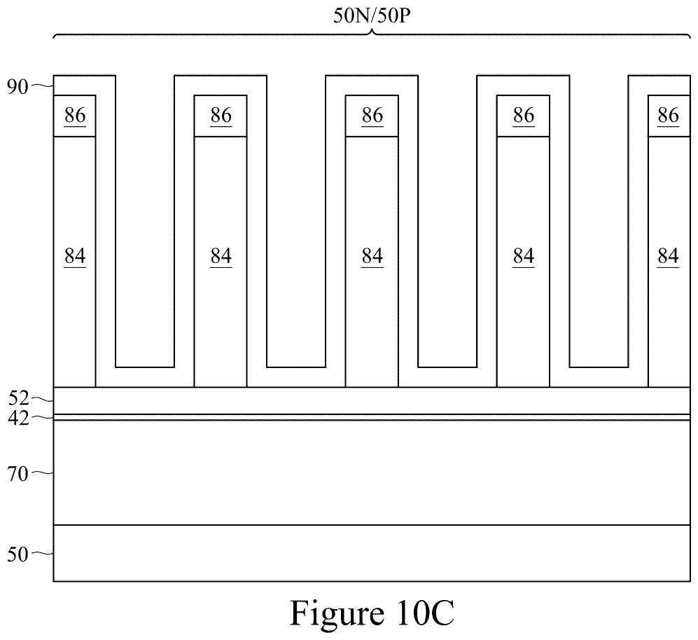

In FIGS. 10A-10C, a spacer layer 90 is conformally formed over the structure, in accordance with some embodiments. The spacer layer 90 is formed over the nanostructures 64/66 and the hard mask 52. The spacer layer 90 is also formed on exposed sidewalls of the masks 86 (if present), the dummy gates 84, the dielectric liner 42, the nanostructures 64/66, and/or the fins 62. The spacer layer 90 may be formed of one or more dielectric material(s). FIGS. 10A-10C show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as CVD, ALD, or the like. Other insulation materials formed by any acceptable process may be used. The spacer layer 90 is subsequently etched to form spacers.

In FIGS. 11A-11D, the spacer layer 90 is patterned to form gate spacers 92 and fin spacers 94, in accordance with some embodiments. Any acceptable etching process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 may have straight sidewalls or may have curved sidewalls. In some embodiments, the etching stops on the hard mask 52. In other embodiments, the hard mask 52 and/or the STI regions 70 may also be etched when patterning the spacer layer 90. For example, the etching may recess portions of the hard mask 52 between fins 62 and/or between gate spacers 92, or may etch through the hard mask 52 and recess portions of the STI regions 70 between fins 62 and/or between gate spacers 92. The etching may stop on the hard mask 52, may recess (e.g., thin) the hard mask 52, or may etch through the hard mask 52, depending on the characteristics of the etching process used. The gate spacers 92 and/or the fin spacers 94 may have straight sidewalls (as illustrated) or may have curved sidewalls (not separately illustrated).

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps May be utilized, additional spacers may be formed and removed, and/or the like. Furthermore, the n-type devices and the p-type devices may be formed using different structures and steps.

Still referring to FIGS. 11A-11C, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the fins 62, and in some embodiments may further extend into the substrate 50. In some embodiments, the fins 62 may be etched such that the bottom surfaces of the source/drain recesses 96 are about level with or higher than top surfaces of the STI regions 70. In other embodiments, bottom surfaces of the source/drain recesses 96 are lower than the top surfaces of the STI regions 70.

The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, and/or the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth. In some embodiments, the etching may etch the hard mask 52, which may form recesses that extend into the STI regions 70 between gate spacers 92.

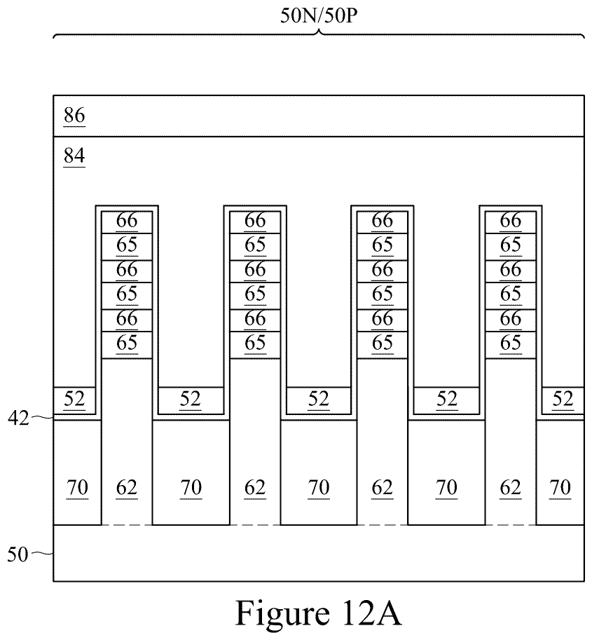

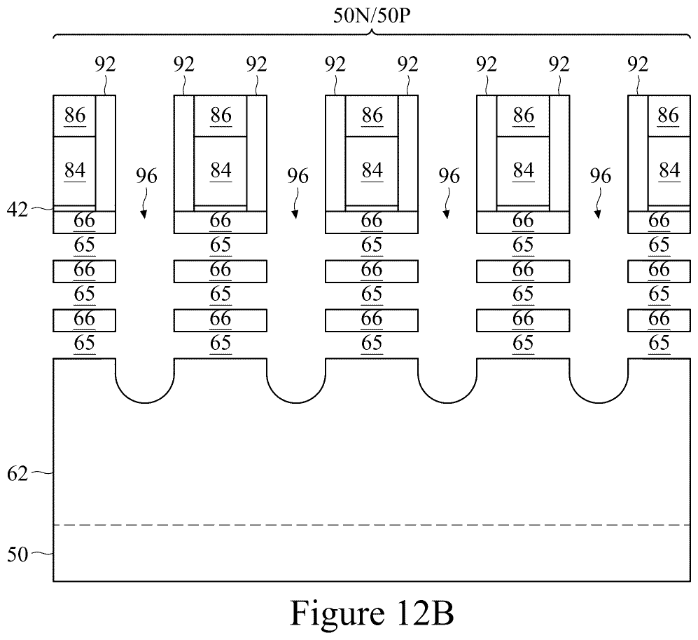

In FIGS. 12A-14B, the first nanostructures 64 are replaced with a dummy material 71 to form dummy regions 72, in accordance with some embodiments. In FIGS. 12A-12B, the remaining portions of the first nanostructures 64 are removed to form openings 65 in regions between the second nanostructures 66, in accordance with some embodiments. The remaining portions of the first nanostructures 64 may be removed using an etching process that is performed through the source/drain recesses 96. The etching process may include any acceptable etching process that selectively etches the material of the first nanostructures 64 at a faster rate than the material of the second nanostructures 66, the fins 62, and/or the dielectric liner 42. The etching process may include a wet etch process and/or a dry etch process, and the etching may isotropic. In some embodiments, a trim process (not illustrated) is performed to decrease the thicknesses of the exposed portions of the second nanostructures 66 and expand the openings 65. Hereinafter, the second nanostructures 66 may be referred to as nanostructures 66, and the collections of vertically adjacent nanostructures 66 over each fin 62 may be referred to as “stacks” of nanostructures 66.

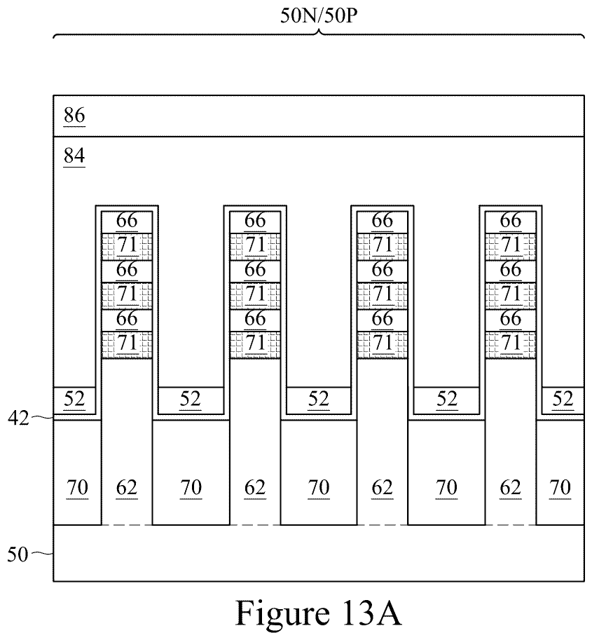

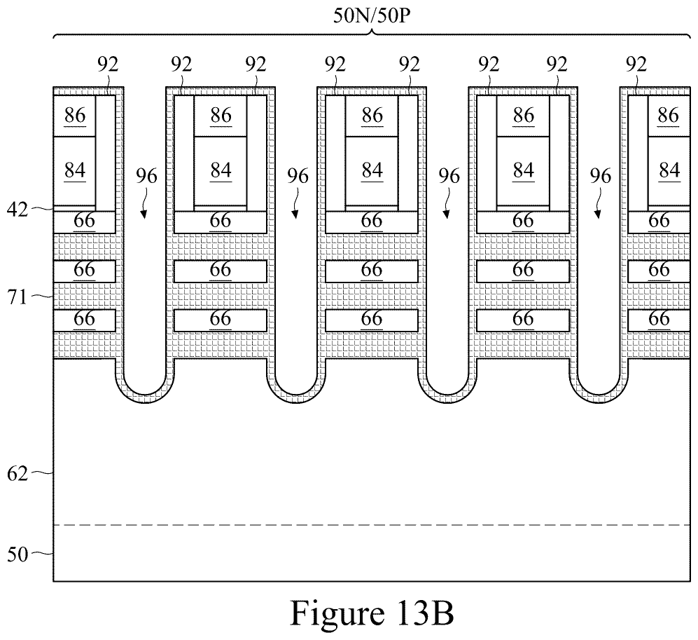

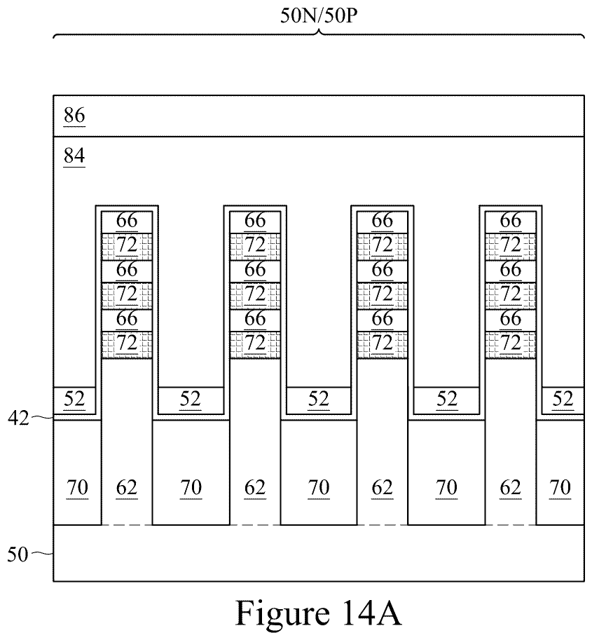

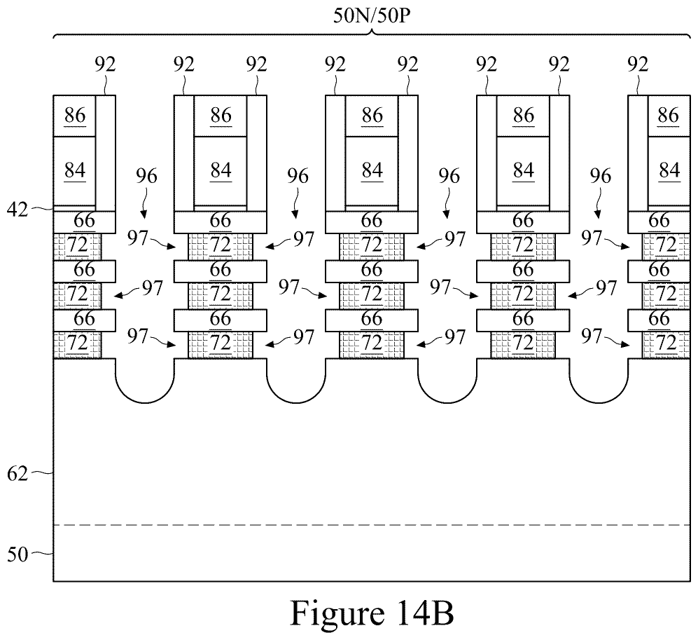

In FIGS. 13A-13B and 14A-14B, the dummy material 71 is deposited to form dummy regions 72, in accordance with some embodiments. In some cases, the dummy material 71 may be considered a sacrificial material or a sacrificial oxide. In some cases, the dummy regions 72 may be considered sacrificial regions, dielectric dummy regions, dummy nanostructures, dummy gate regions, or disposable oxide interposers (DOI). Replacing the first nanostructures 64 with dummy regions 72 may provide advantages. For example, in subsequent source/drain formation steps, one or more high temperature processes may be performed to, for example, activate the dopants in the source/drain regions. When the material of the first nanostructures 64 (e.g., silicon germanium or the like) is exposed to high temperatures, germanium intermixing and increased roughness at interfaces between the nanostructures 64 and 66 may result. Such manufacturing defects may degrade the performance of the resulting transistor devices. For example, when germanium diffuses into the second nanostructures 66, germanium residue may remain in channel regions of the resulting transistor devices, which negatively affects the performance of the channel regions. Additionally, the intermixing may result in etching selective to either the first nanostructures 64 or the second nanostructures 66 to be less effective and less defined. This can result in, for example, portions of the second nanostructures 66 being undesirably removed, which can damage features, reduce yield, and/or degrade device performance. By replacing the first nanostructures 64 with an insulating material (e.g., the dummy material 71) prior to the high temperature processes (e.g., source/drain annealing), manufacturing defects can be reduced and device performance can be improved. Additionally, the selectivity of etching between the dummy material 71 and the material of the second nanostructures 66 may be greater than the selectivity of etching between the nanostructures 64 and 66, allowing for improved etching definition and less etching of the second nanostructures 66.

In FIGS. 13A-13B, a dummy material 71 is deposited in the recesses 96 and in the openings 65, in accordance with some embodiments. The dummy material 71 may be deposited by a conformal deposition process, such as CVD, ALD, or the like. The dummy material 71 may comprise an insulating material such as silicon oxide or the like that can be selectively etched from the nanostructures 66 and the fins 62. In some embodiments, the dummy material 71 and the hard mask 52 may be different materials. In other embodiments, the dummy material 71 and the hard mask 52 may be similar materials. As shown in FIGS. 13A-13B, the dummy material 71 may fill or overfill the openings 65 and may cover sidewalls of the nanostructures 66. The dummy material 71 may cover top surfaces of the fins 62. In some embodiments, the dummy material 71 does not completely fill the source/drain recesses 96.

In FIGS. 14A-14B, the dummy material 71 is etched to form the dummy regions 72, in accordance with some embodiments. The etching may be isotropic or anisotropic. For example, the dummy material 71 may be etched using a wet etch process, such as dHF or the like. In some embodiments, the etching is performed until sidewalls of the dummy material 71 are recessed past sidewalls of the nanostructures 66, forming sidewall recesses 97. Accordingly, the dummy regions 72 may have a width that is smaller than a width of the nanostructures 66. In some cases, the sidewall recesses 97 may be considered part of the source/drain recesses 96. Although sidewalls of the dummy regions 72 within the sidewall recesses 97 are illustrated as being flat, the sidewalls may be concave or convex.

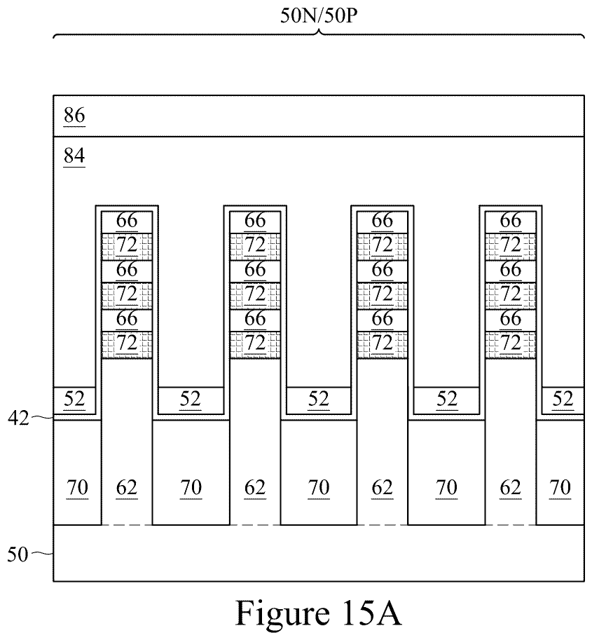

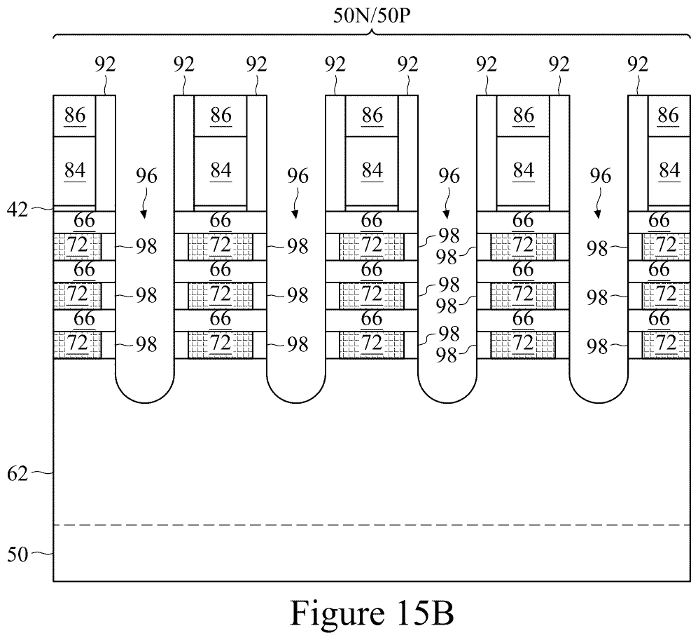

In FIGS. 15A-15B, inner spacers 98 are formed in the sidewall recesses 97, in accordance with some embodiments. In other words, inner spacers 98 are formed on the sidewalls of the dummy regions 72. As will be subsequently described in greater detail, source/drain regions are subsequently formed in the source/drain recesses 96, and the dummy regions 72 are subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes.

In some embodiments, the inner spacers 98 are formed by conformally depositing an insulating material in the source/drain recesses 96 and in the sidewall recesses 97 and subsequently etching the insulating material. The insulating material may be silicon nitride, silicon oxynitride, or the like. However, any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98. An inner spacer 98 may have a thickness that is smaller than, about the same as, or greater than a thickness of an adjacent dummy region 72.

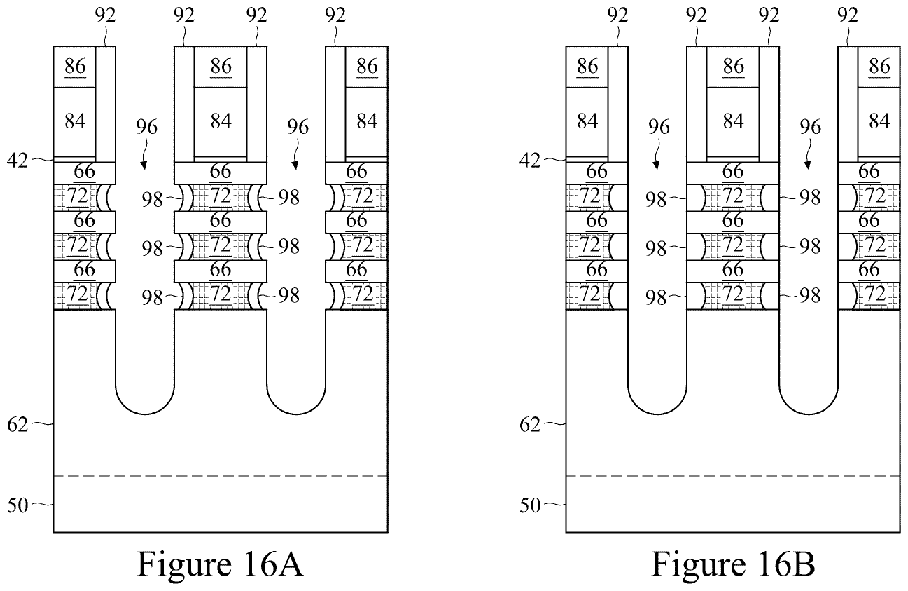

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat in FIGS. 15A-15B, the sidewalls of the inner spacers 98 may be concave or convex. As an example, FIG. 16A illustrates an embodiment in which sidewalls of the dummy regions 72 are concave, outer sidewalls of the inner spacers 98 are concave, and inner spacers 98 are recessed from sidewalls of the nanostructures 66. As another example, FIG. 16B illustrates an embodiment in which sidewalls of the dummy regions 72 are concave, outer sidewalls of the inner spacers 98 are flat, and outer sidewalls of the inner spacers 98 are flush with sidewalls of the nanostructures 66. Other configurations or sidewall profiles are also possible.

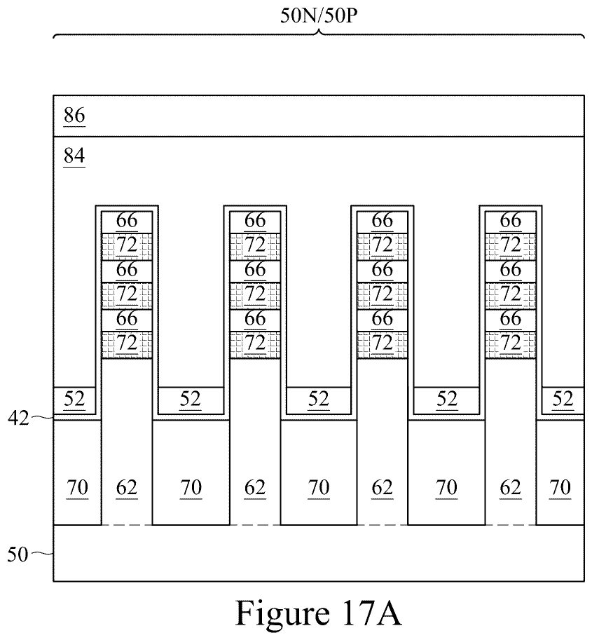

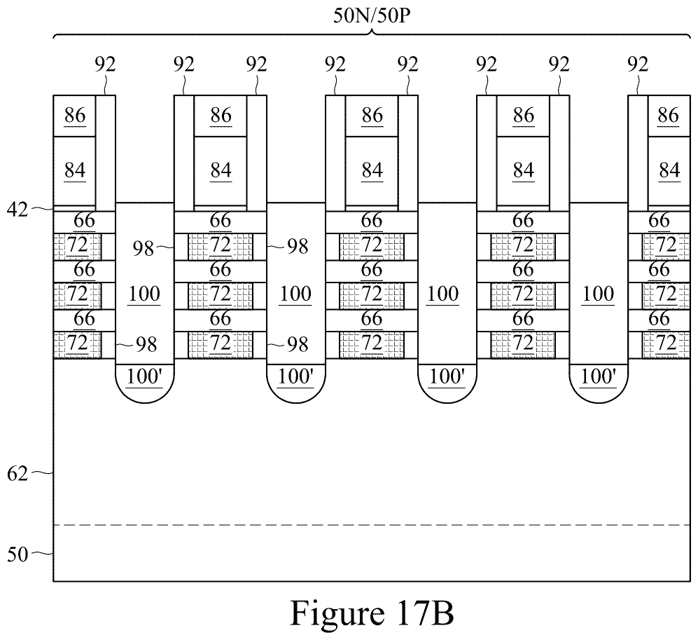

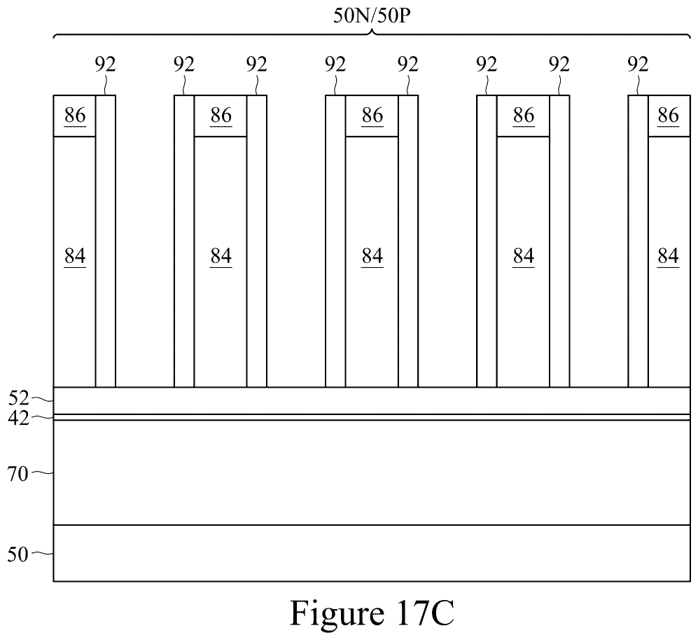

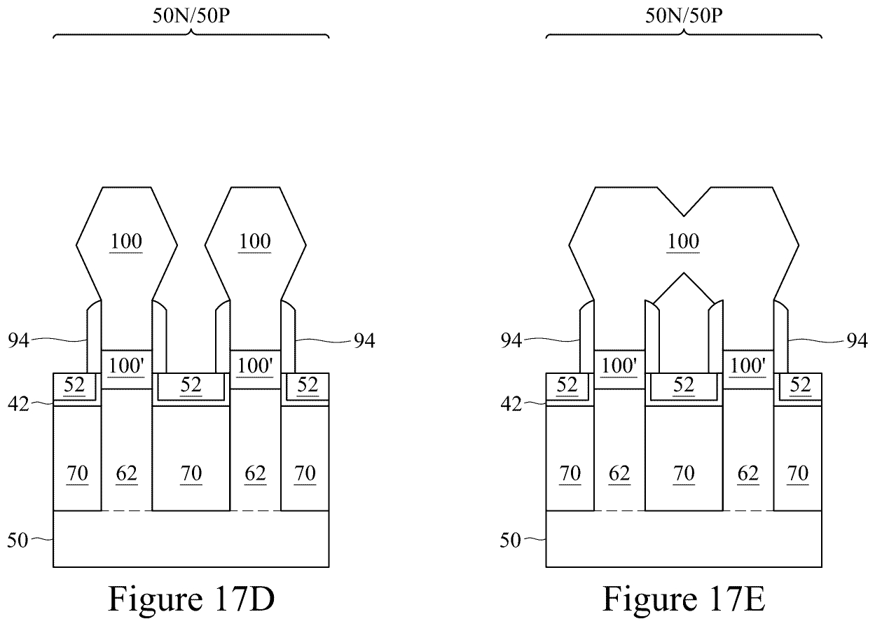

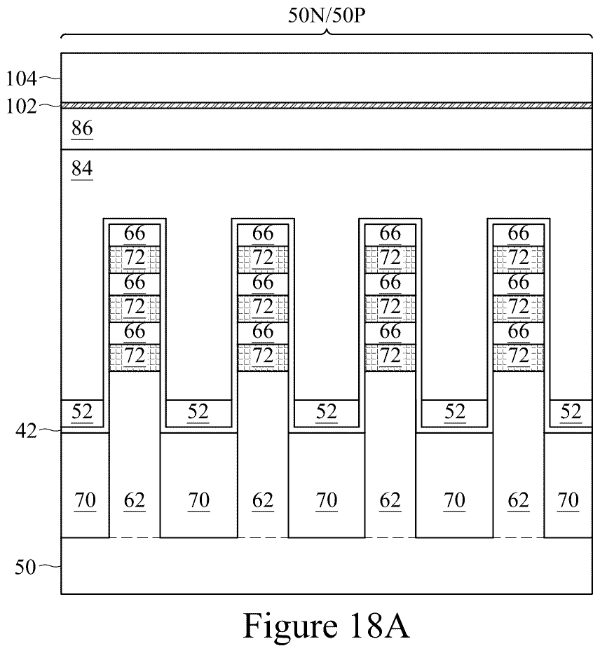

In FIGS. 17A-17E, epitaxial source/drain regions 100 are formed in the source/drain recesses 96 of the n-type region 50N and in the source/drain recesses 96 of the p-type region 50P, in accordance with some embodiments. The epitaxial source/drain regions 100 may also be referred to as “source/drain regions 100.” For example, the epitaxial source/drain regions 100 in the n-type region 50N may be referred to as “n-type source/drain regions 100,” and the epitaxial source/drain regions 100 in the p-type region 50P may be referred to as “p-type source/drain regions 100.” The n-type source/drain regions 100 may be formed before, after, or simultaneously with the formation of the p-type source/drain regions 100. The epitaxial source/drain regions 100 may be formed by an epitaxy process, such as such as vapor phase epitaxy (VPE), molecular beam epitaxy (MBE), or the like.

In some embodiments, semiconductor layers 100′ may be formed in the source/drain recesses 96 before forming the epitaxial source/drain regions 100 in the source/drain recesses 96. The semiconductor layers 100′ may comprise, for example, undoped silicon or the like. Although the top surfaces of the semiconductor layers 100′ are illustrated as being flat (e.g., planar), the top surfaces of the semiconductor layers 100′ may be concave or convex. Top surfaces of the semiconductor layers 100′ may be higher than, approximately level with, or below top surfaces of the fins 62. In some embodiments, the semiconductor layers 100′ are not in physical contact with the inner spacers 98. In other embodiments, the semiconductor layers 100′ may be in physical contact with the sidewalls of some inner spacers 98. In some cases, the semiconductor layers 100′ may be considered part of the corresponding epitaxial source/drain regions 100. In other embodiments, an insulating layer (not illustrated) may be deposited in the source/drain recesses 96 before forming the epitaxial source/drain regions 100 in the source/drain recesses 96.

In some embodiments, the epitaxial source/drain regions 100 exert stress on channel regions of the nanostructures 66 within the n-type region 50N and/or within the p-type region 50P, thereby improving performance. The epitaxial source/drain regions 100 are formed in the source/drain recesses 96 such that each dummy gate 84 of the p-type region 50P is disposed between respective neighboring pairs of the epitaxial source/drain regions 100. In some embodiments, the gate spacers 92 are used to separate the epitaxial source/drain regions 100 from the dummy gates 84, and the inner spacers 98 are used to separate the epitaxial source/drain regions 100 from the nanostructures 66 by an appropriate lateral distance such that the epitaxial source/drain regions 100 do not short out with subsequently formed gates of the resulting nanostructure-FETs.

The epitaxial source/drain regions 100 in the n-type region 50N may be formed by masking the p-type region 50P. Then, n-type source/drain regions 100 are epitaxially grown in the source/drain recesses 96 in the n-type region 50N. The n-type source/drain regions 100 may include any acceptable material appropriate for n-type nanostructure-FETs. For example, if the nanostructures 66 are silicon, the n-type source/drain regions 100 may include materials exerting a tensile strain on the nanostructures 66, such as silicon, silicon carbide, phosphorous doped silicon carbide, silicon phosphide, or the like.

The epitaxial source/drain regions 100 in the p-type region 50P may be formed by masking the n-type region 50N. Then, p-type source/drain regions 100 are epitaxially grown in the source/drain recesses 96 in the p-type region 50P. The p-type source/drain regions 100 may include any acceptable material appropriate for p-type nanostructure-FETs. For example, if the nanostructures 66 are silicon, the p-type source/drain regions 100 may include materials exerting a compressive strain on the nanostructures 66, such as silicon germanium, boron doped silicon germanium, germanium, germanium tin, or the like.

The epitaxial source/drain regions 100, nanostructures 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 100 may be in situ doped during growth.

As a result of the epitaxy processes used to form the epitaxial source/drain regions 100 in the n-type region 50N and the p-type region 50P, upper surfaces of the epitaxial source/drain regions 100 have facets which expand laterally outward beyond sidewalls of the nanostructures 66. In some embodiments, adjacent epitaxial source/drain regions 100 remain separated after the epitaxy process is completed, as illustrated by FIG. 17D. In other embodiments, these facets cause adjacent epitaxial source/drain regions 100 of a same nanostructure-FET to merge, as illustrated by FIG. 17E. In the embodiments illustrated in FIGS. 17D and 17E, the fin spacers 94 may be formed on top surfaces of the STI regions 70, thereby blocking epitaxial growth. In some other embodiments, the fin spacers 94 may cover portions of the sidewalls of the nanostructures 66, further blocking the epitaxial growth. In some other embodiments, the spacer etch used to form the fin spacers 94 may be adjusted to remove the spacer material to allow the epitaxially grown region to extend to the surface of the hard mask 52.

The n-type source/drain regions 100 and/or the p-type source/drain regions 100 may comprise one or more semiconductor material layers. Any number of semiconductor material layers may be used for the epitaxial source/drain regions 100. Each semiconductor material layer may be formed of different semiconductor materials and may be doped to different dopant concentrations. In embodiments in which the epitaxial source/drain regions 100 comprise three semiconductor material layers, the first semiconductor material layer may be deposited, the second semiconductor material layer may be deposited over the first semiconductor material layer, and the third semiconductor material layer may be deposited over the second semiconductor material layer. In some embodiments, the first semiconductor material layer may have a dopant concentration less than the second semiconductor material layer and greater than the third semiconductor material layer. Other semiconductor material layers, dopant concentrations, or configurations thereof are possible.

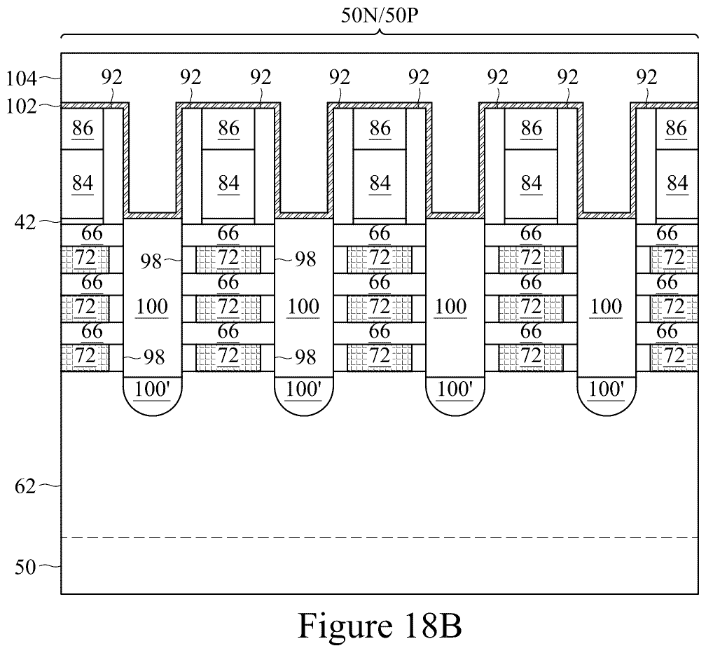

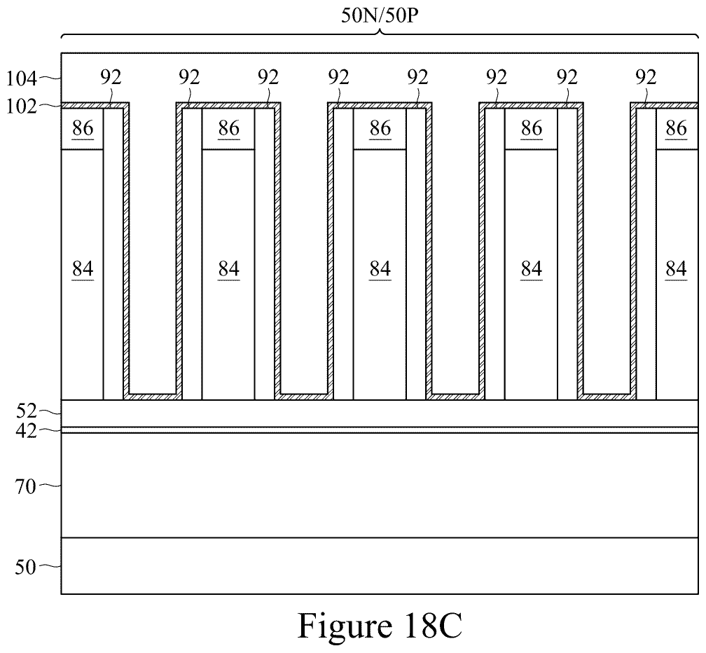

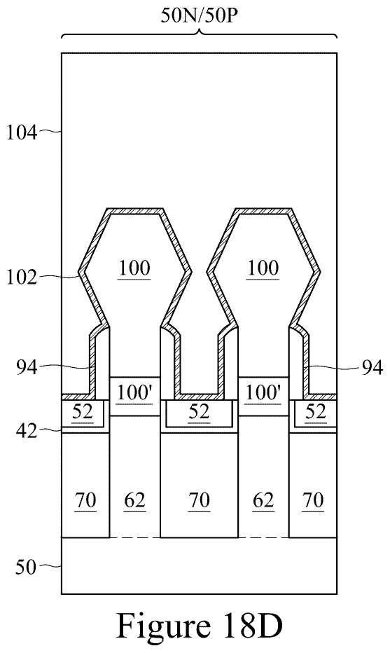

In FIGS. 18A-18D, a first ILD 104 is deposited over the epitaxial source/drain regions 100, the fin spacers 94, the gate spacers 92, the masks 86 (if present), the hard mask 52, and/or the dummy gates 84. The first ILD 104 may be formed of a dielectric material, which may be deposited by any suitable method, such as CVD, PECVD, or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some cases, the first ILD 104 may extend below top surfaces of the hard mask 52 and/or below bottom surfaces of the epitaxial source/drain regions 100.

In some embodiments, a Contact Etch Stop Layer (CESL) 102 is formed between the first ILD 104 and the epitaxial source/drain regions 100, the fin spacers 94, the gate spacers 92, the masks 86 (if present), the hard mask 52, and/or the dummy gates 84. The CESL 102 may be formed of a dielectric material having a high etching selectivity from the etching of the first ILD 104, such as silicon nitride, silicon oxide, silicon oxynitride, a combination thereof, or the like, which may be formed using any suitable deposition process, such as CVD, ALD, or the like. In other embodiments, the masks 86 and portions of the gate spacers 92 along sidewalls of the masks 86 are removed using a planarization process (e.g., a CMP or grinding process) prior to deposition of the CESL 102 and the first ILD 104.

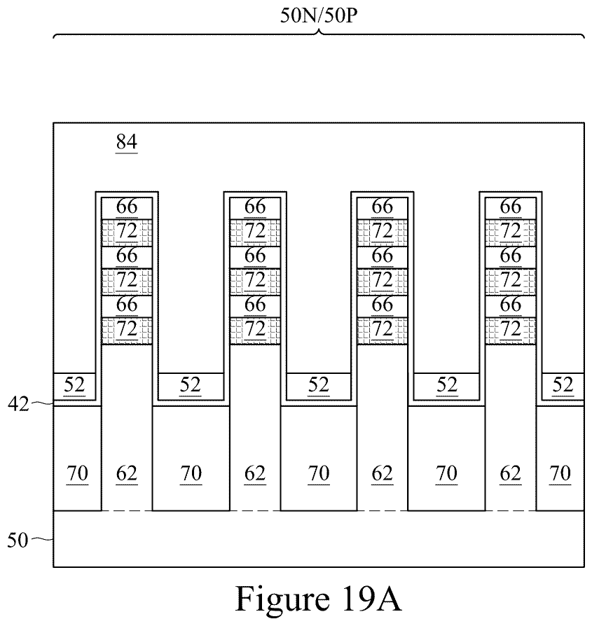

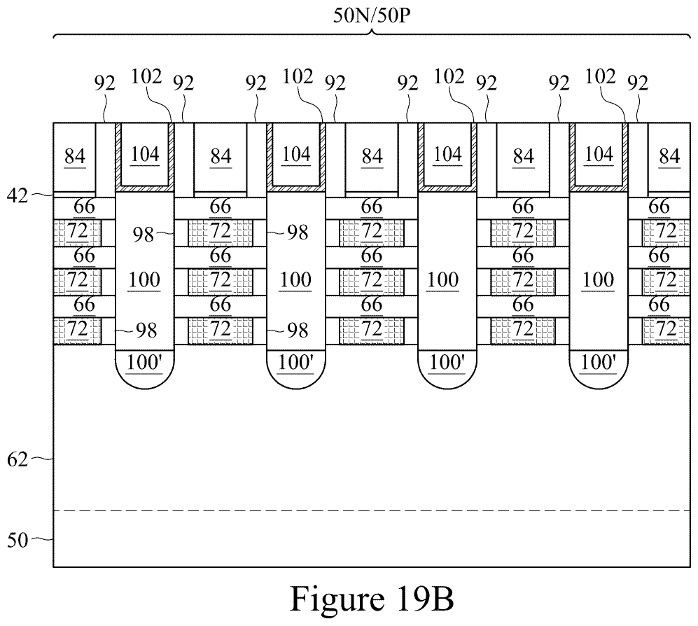

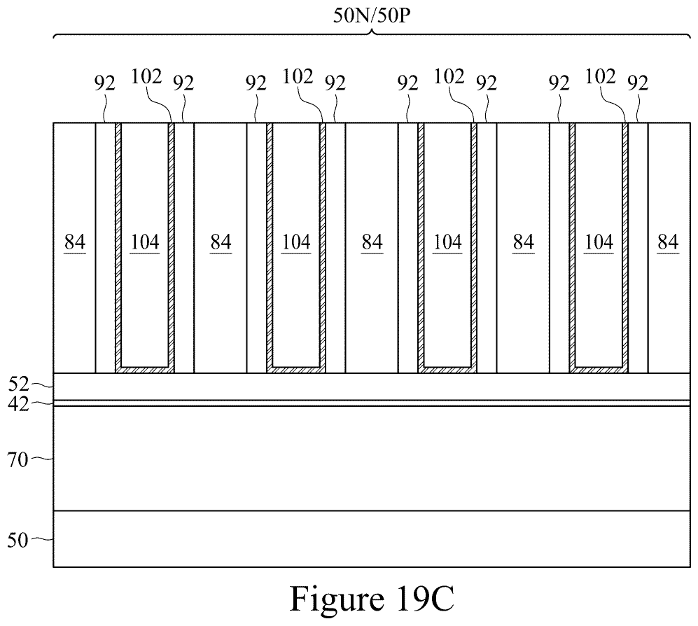

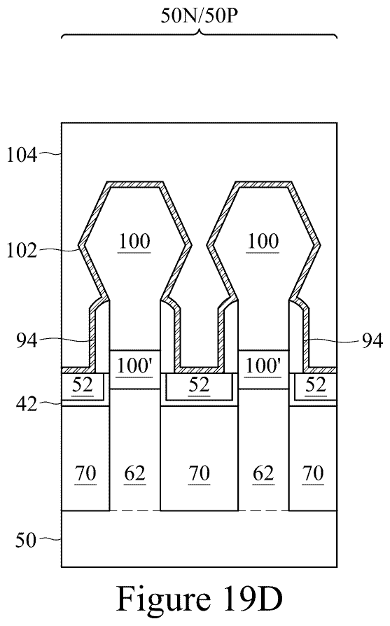

In FIGS. 19A-19D, a removal process is performed to level the top surfaces of the first ILD 104 with the top surfaces of the gate spacers 92 and the dummy gates 84, in accordance with some embodiments. In some embodiments, the planarization process removes the masks 86 and portions of the gate spacers 92 along sidewalls of the masks 86. The removal process may include a planarization process such as a CMP process, a grinding process, an etch-back process, a combination thereof, or the like. After the planarization process, top surfaces of the first ILD 104, the gate spacers 92, and the dummy gates 84 may be substantially level or coplanar (within process variations). Accordingly, the top surfaces of the dummy gates 84 may be exposed through the first ILD 104. In other embodiments, the planarization process does not remove the masks 86. In such embodiments, after the planarization process, top surfaces of the first ILD 104, the gate spacers 92, and the masks 86 may be substantially level or coplanar (within process variations).

In some embodiments, a capping layer (not illustrated) is formed over the first ILD 104. The capping layer may be formed, for example, by recessing the first ILD 104 using a suitable etching process and then depositing an insulating material over the structure. The insulating material may comprise one or more dielectric materials such as silicon nitride, silicon oxynitride, or the like. A planarization process (e.g., a CMP or grinding process) may then be performed to remove excess insulating material from over the structure, with the remaining insulating material over the first ILD 104 forming the capping layer. In other embodiments, the capping layer is not formed.

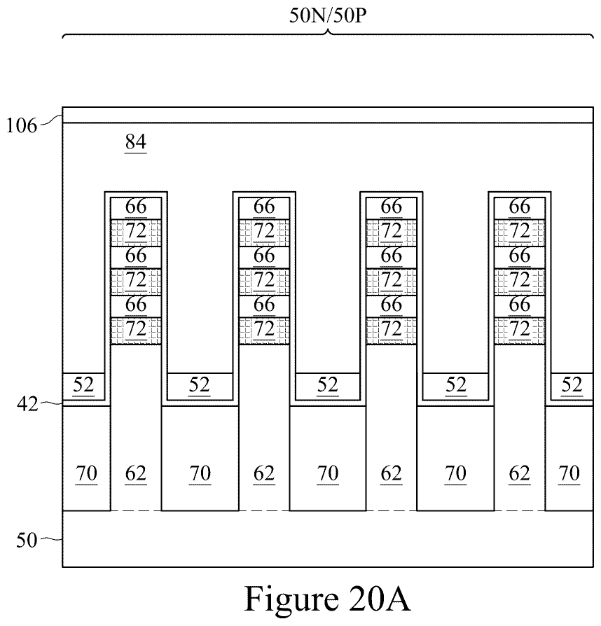

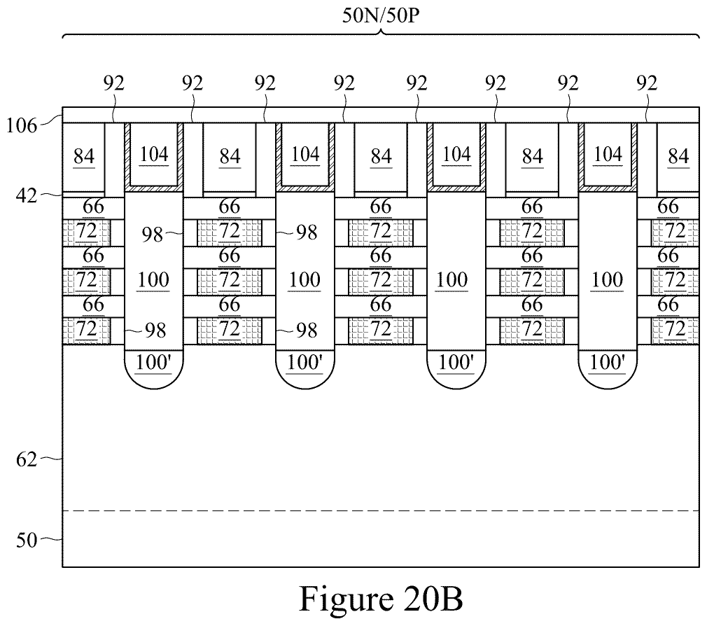

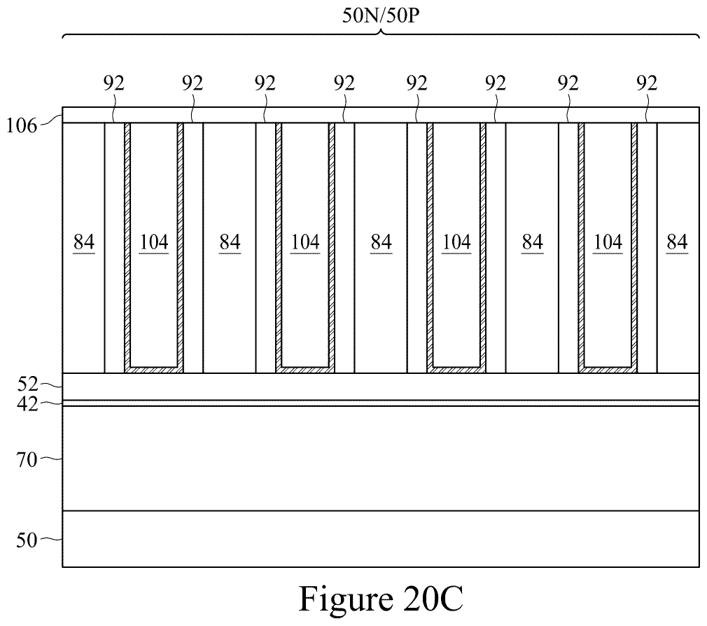

FIGS. 20A-26C illustrate intermediate steps in the formation of transistor isolation regions 116 (see FIGS. 26A-26C), in accordance with some embodiments. The transistor isolation regions 116 separate and isolate (e.g., “cut”) subsequently formed gate structures. Accordingly, in some cases, the transistor isolation regions 116 may be considered gate isolation regions or the like. In some cases, the transistor isolation regions 116 may be considered Cut Poly On Diffusion Edge (CPODE) structures or the like. The techniques herein allow for the formation of transistor isolation regions 116 with reduced risk of fin 62 damage and reduced risk of parasitic transistor formation, described in greater detail below.

In FIGS. 20A-20C, a hard mask layer 106 is formed over the structure, in accordance with some embodiments. The hard mask layer 106 may include one or more layers of dielectric materials, such as silicon nitride, silicon oxynitride, a metal oxide, or the like. As shown in FIGS. 20A-20C, the hard mask layer 106 is deposited over surfaces of the dummy gates 84, the gate spacers 92, the first ILD 104, and the CESL 102. The hard mask layer 106 may be deposited using a suitable technique, such as CVD, PECVD, ALD, or the like.

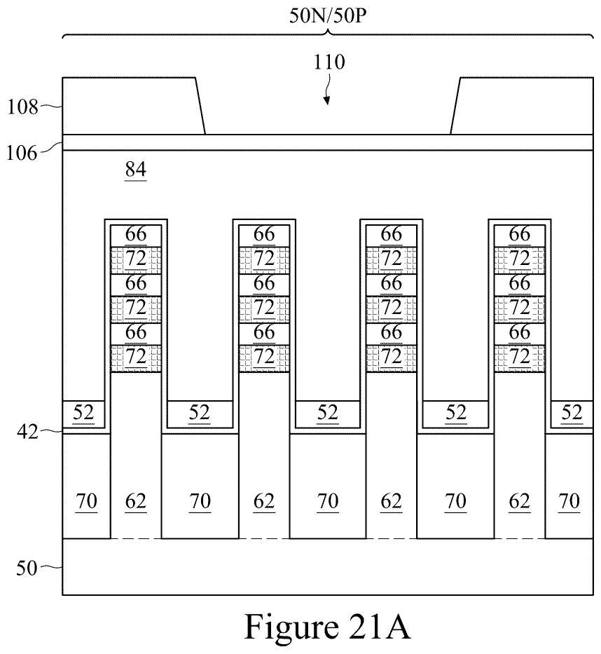

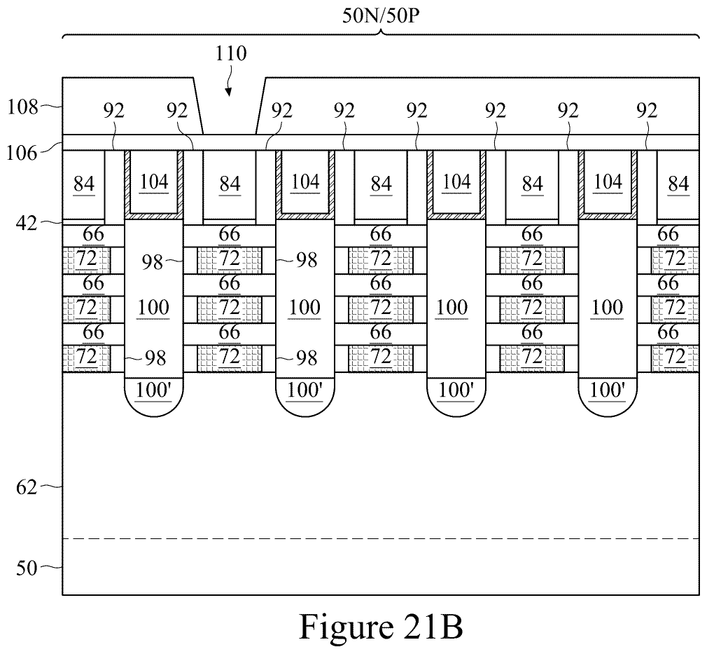

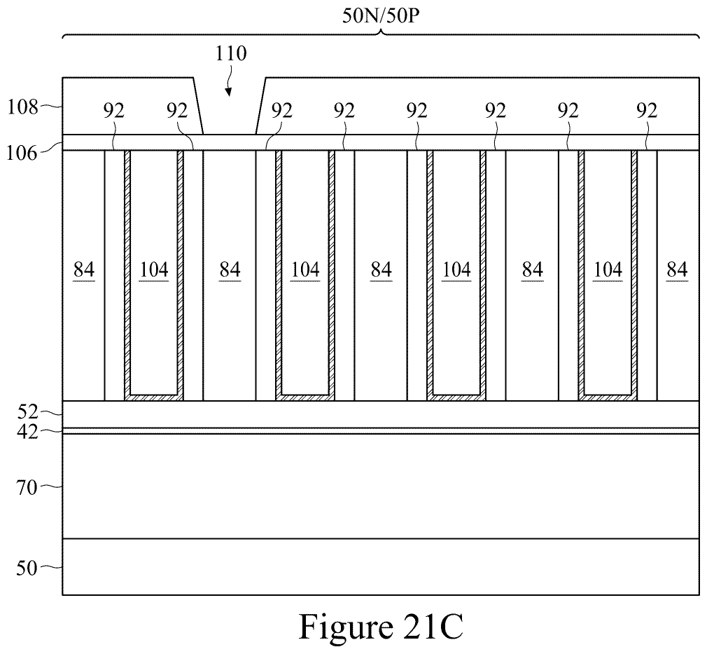

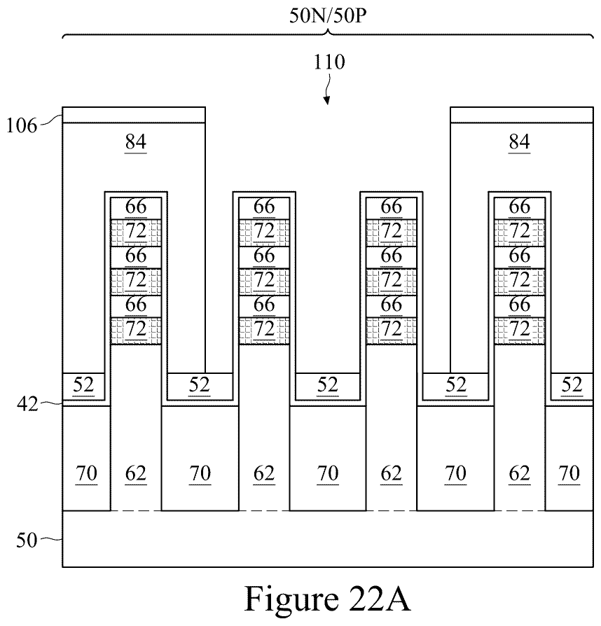

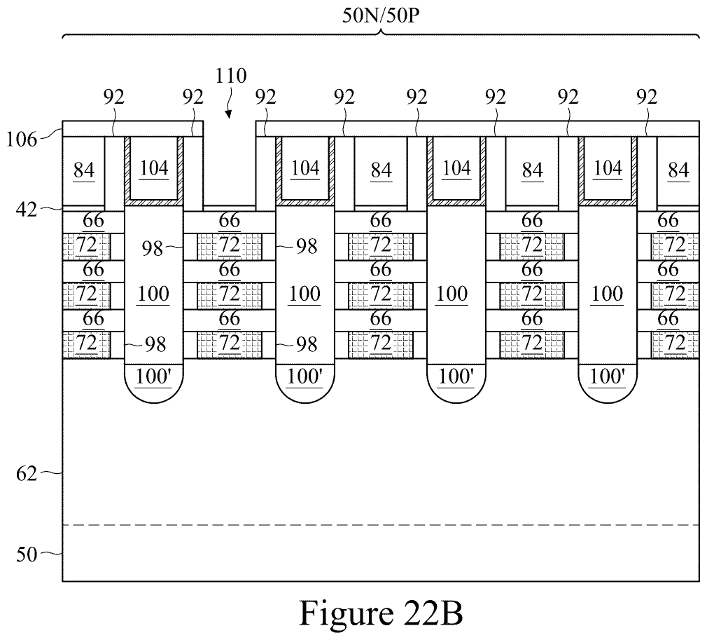

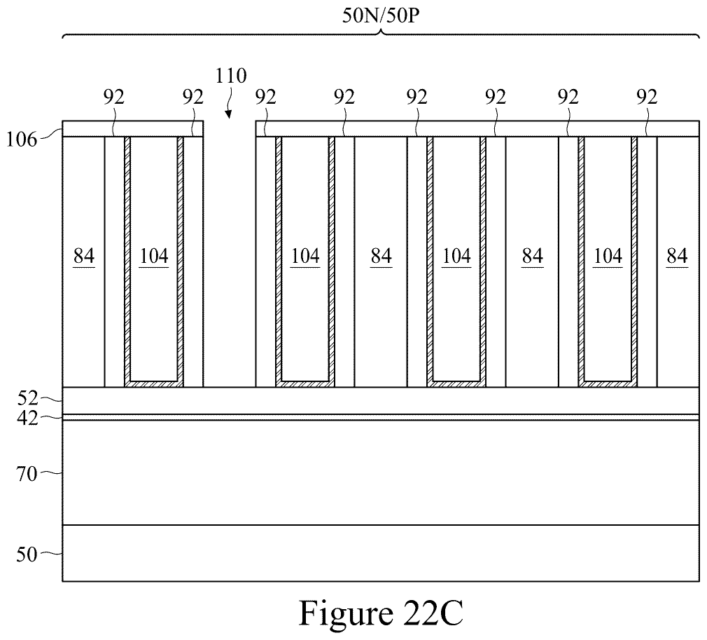

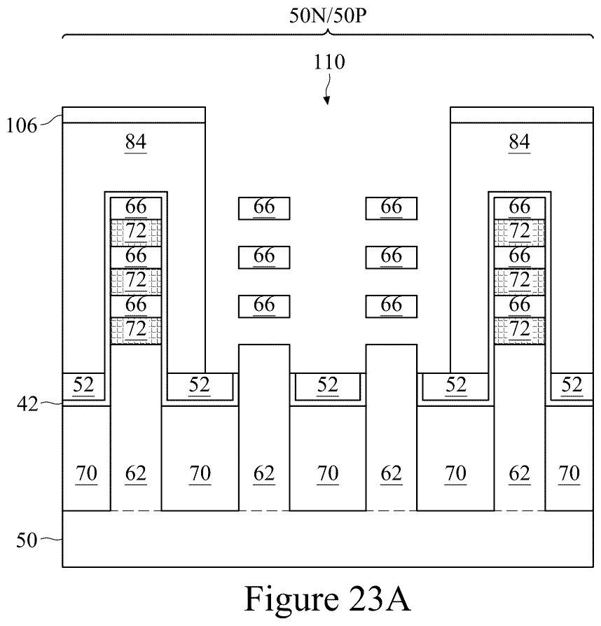

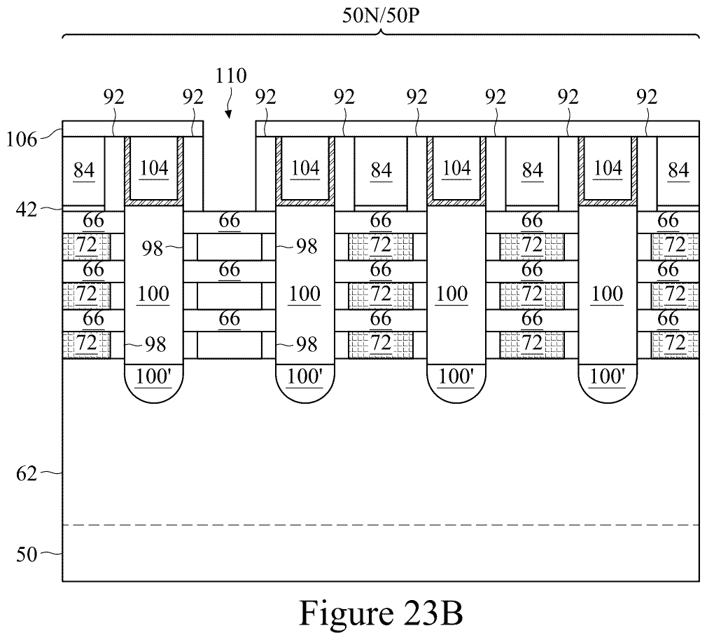

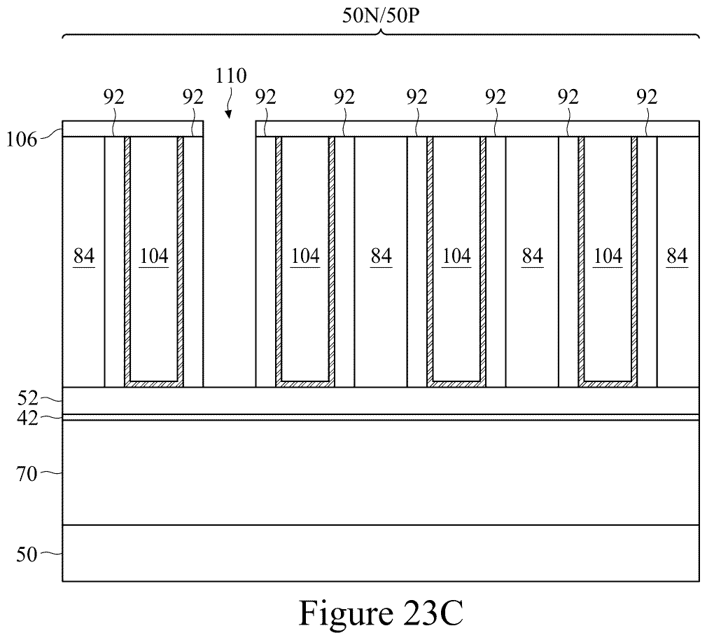

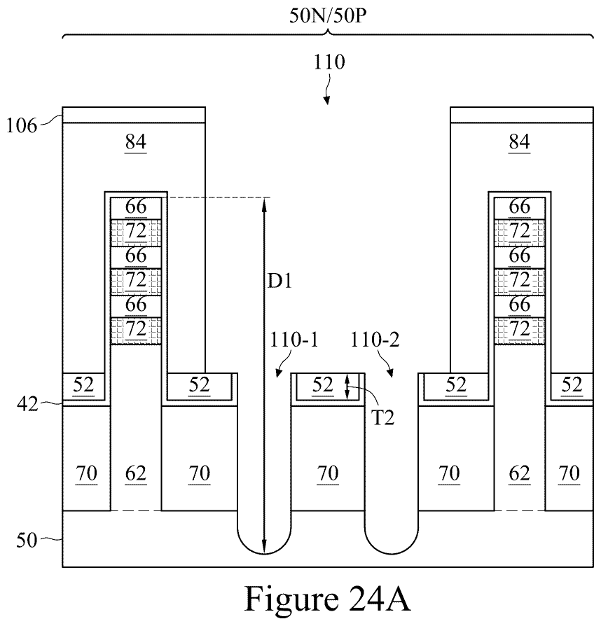

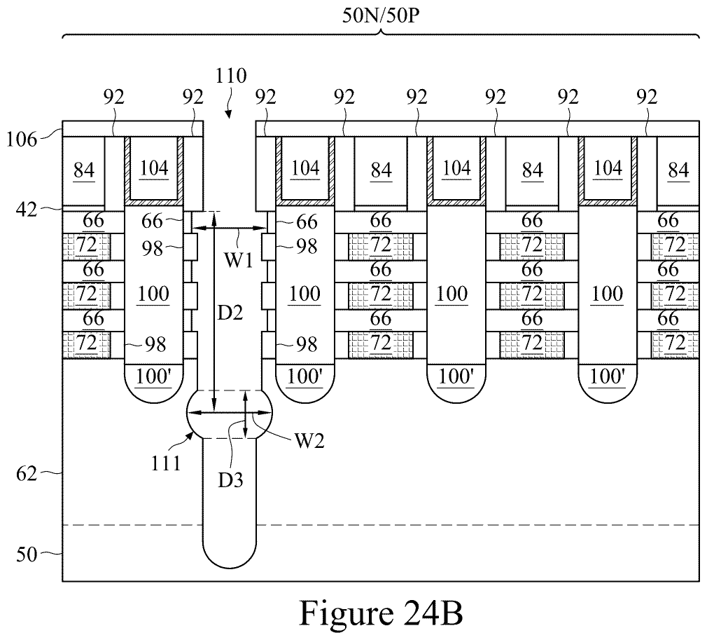

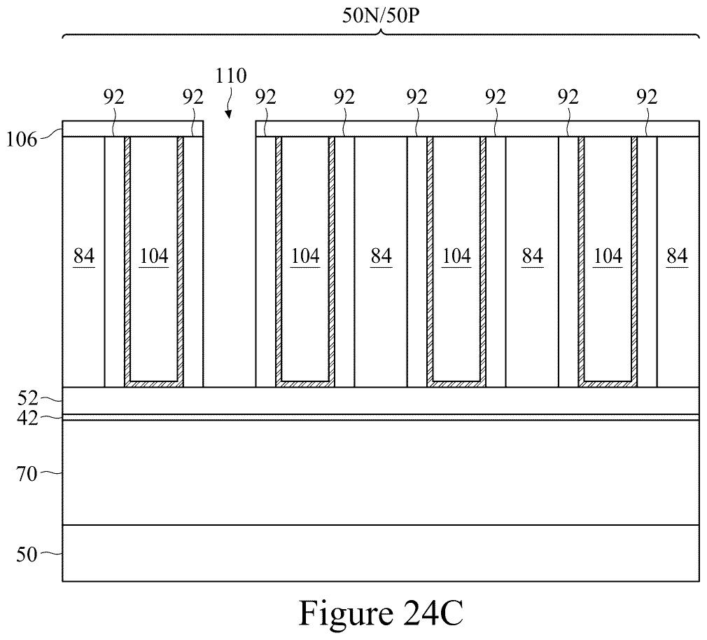

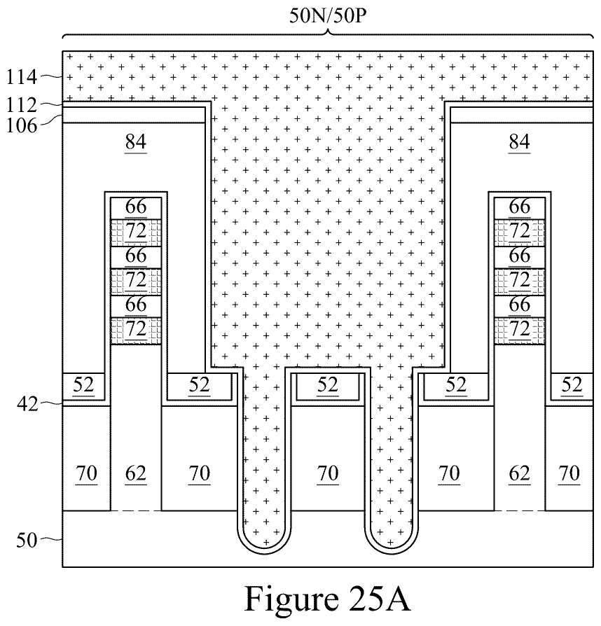

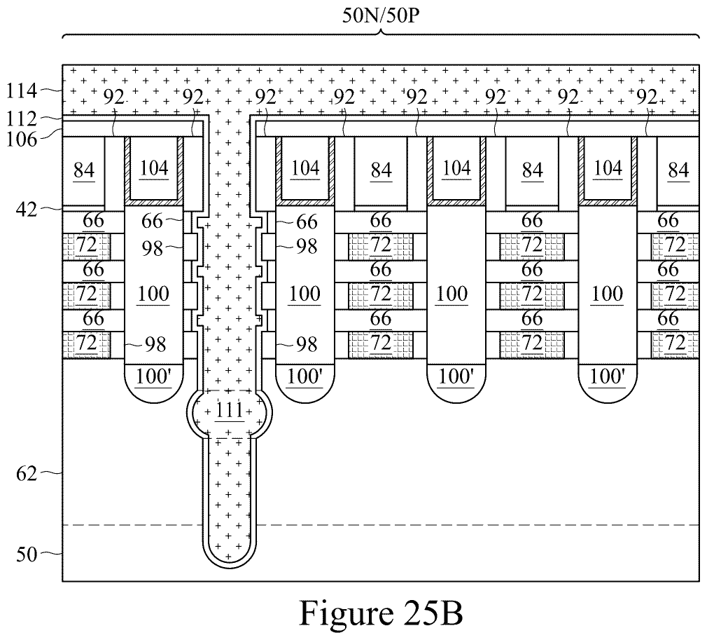

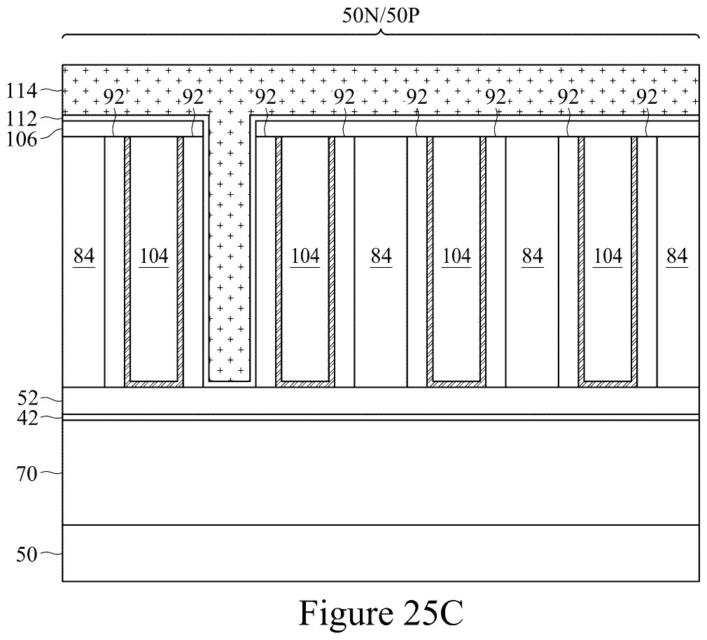

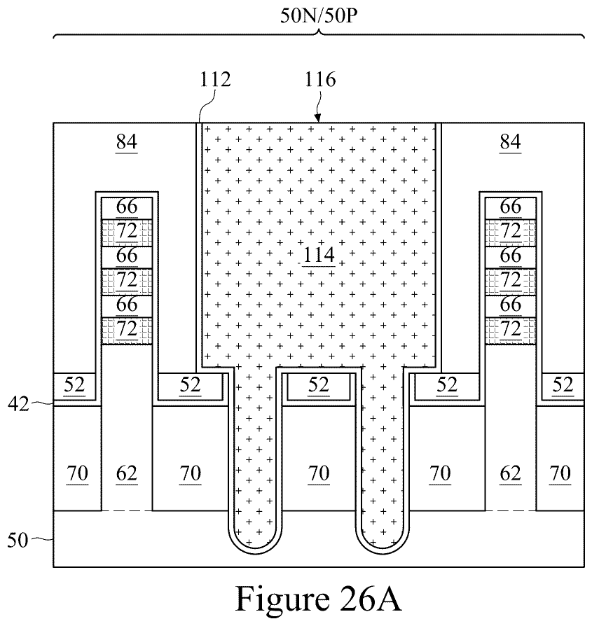

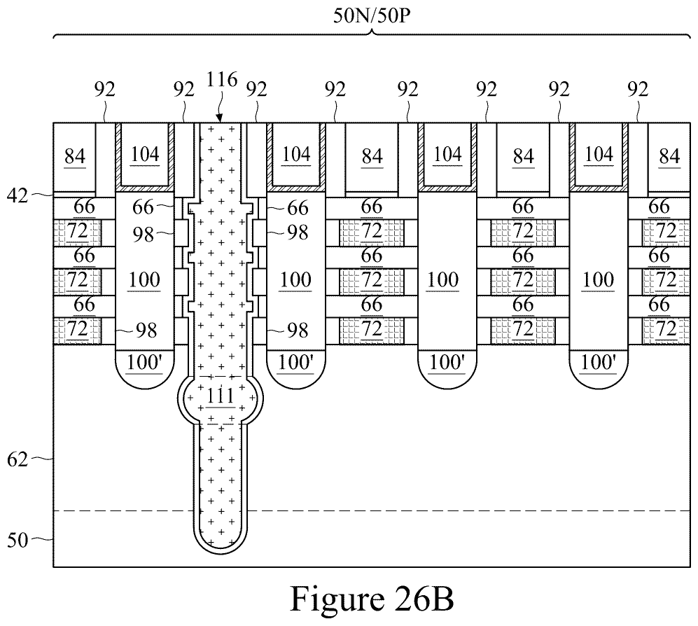

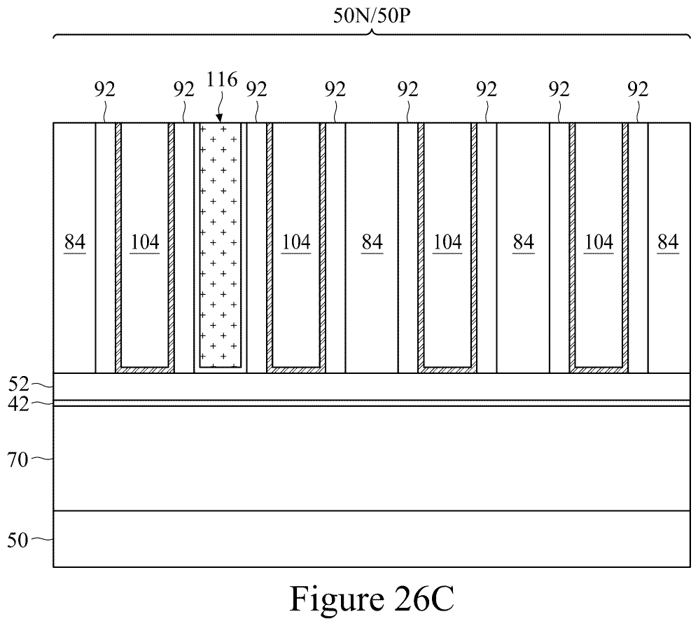

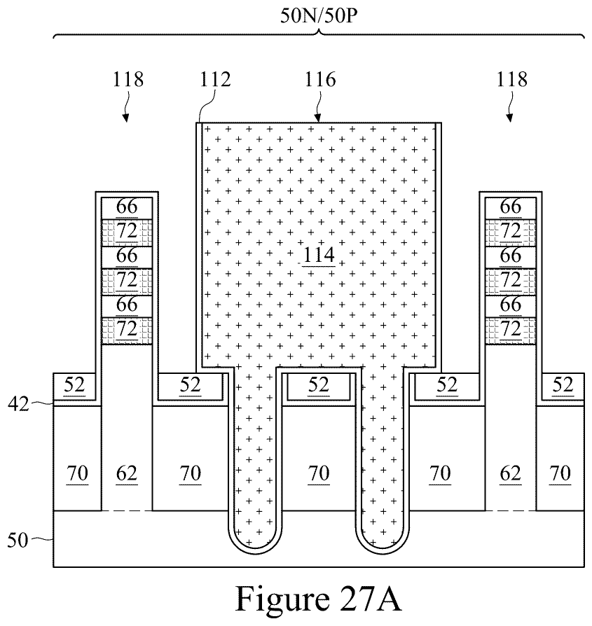

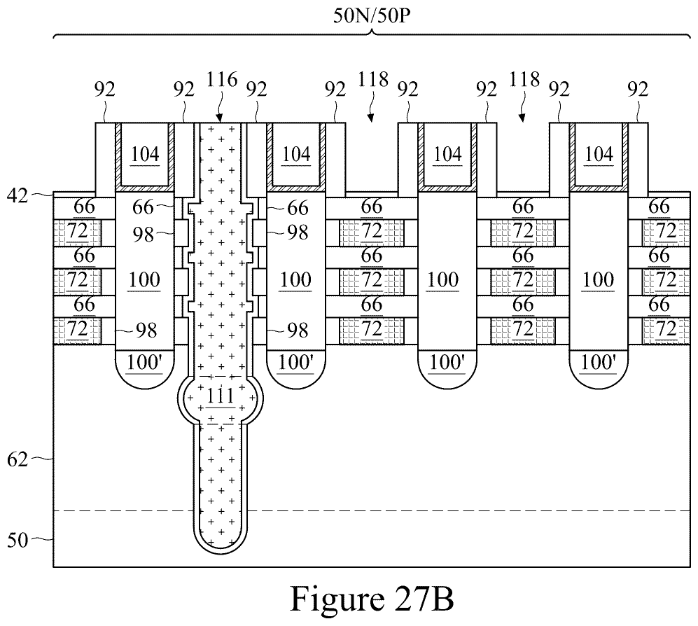

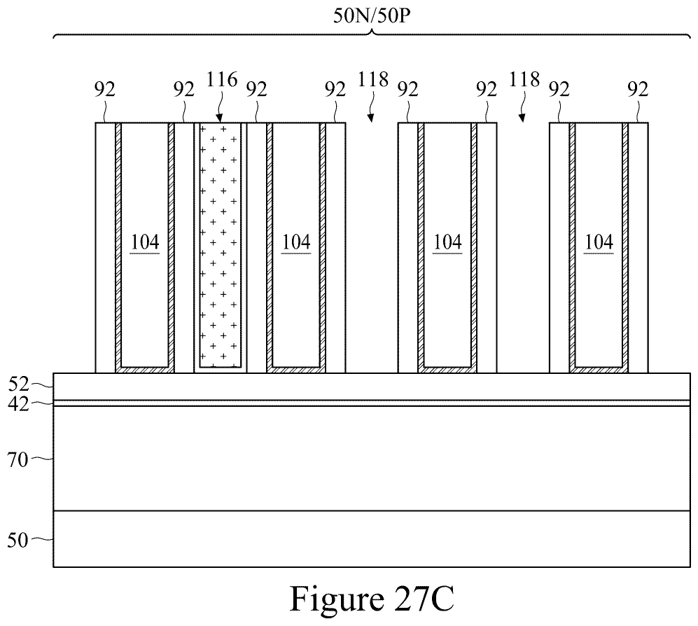

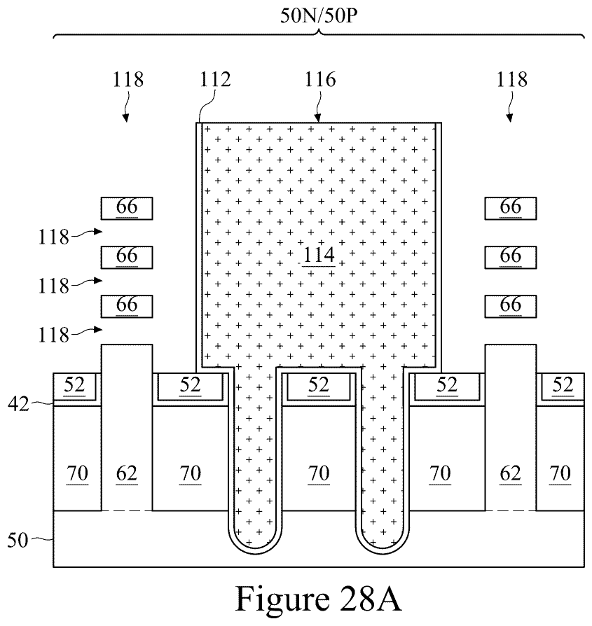

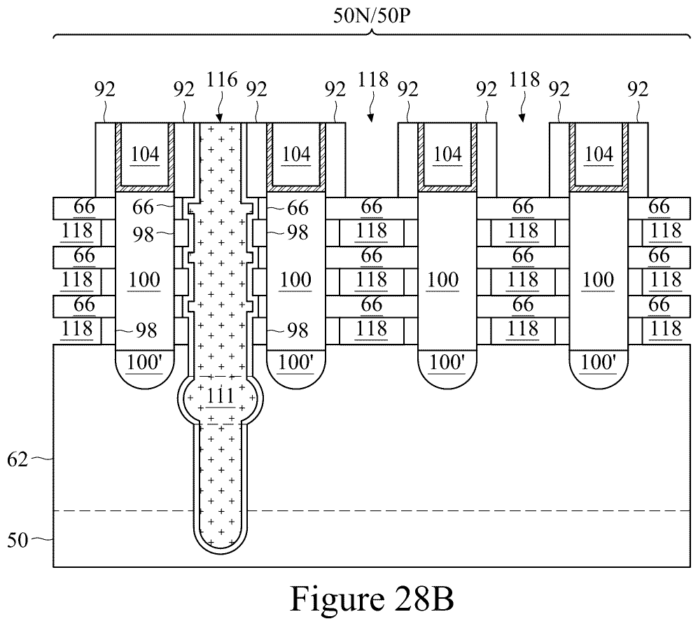

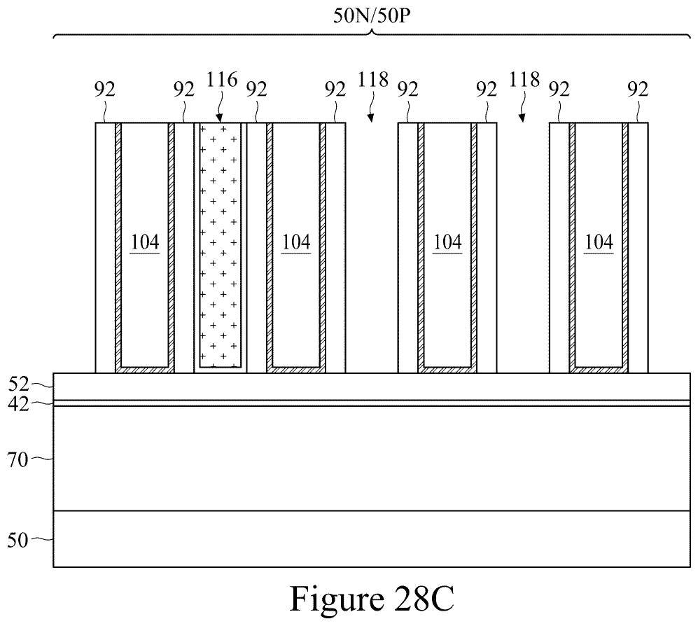

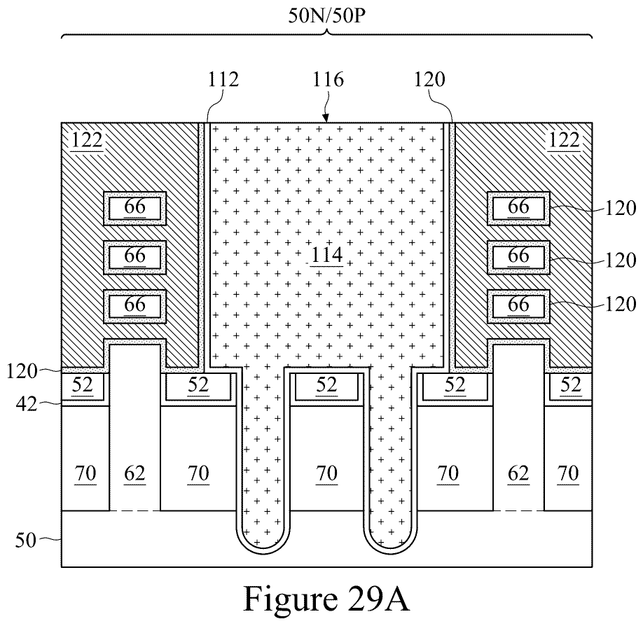

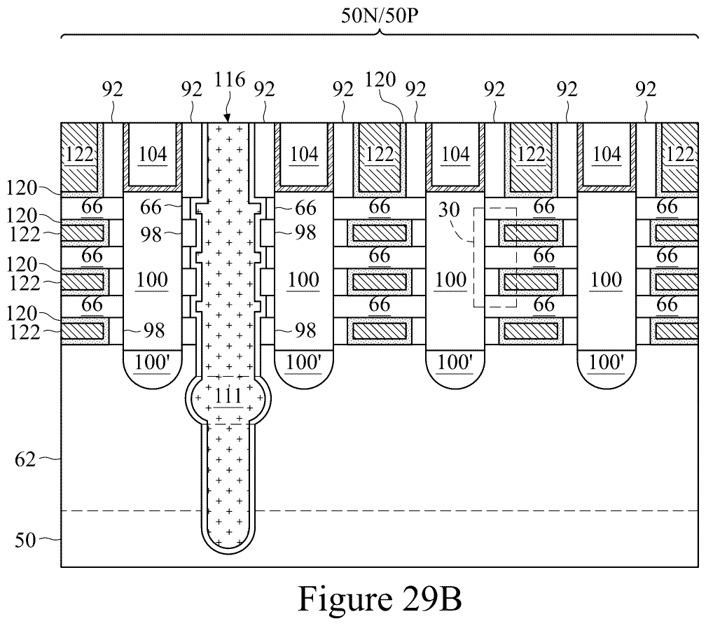

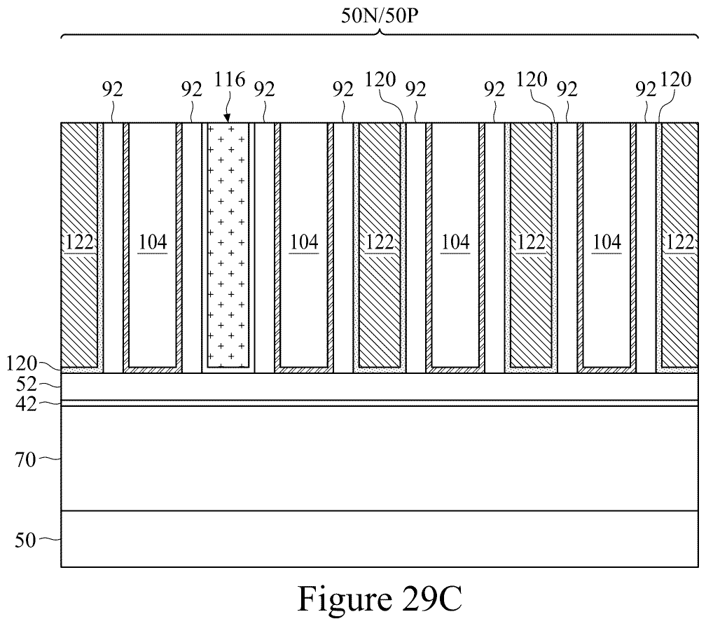

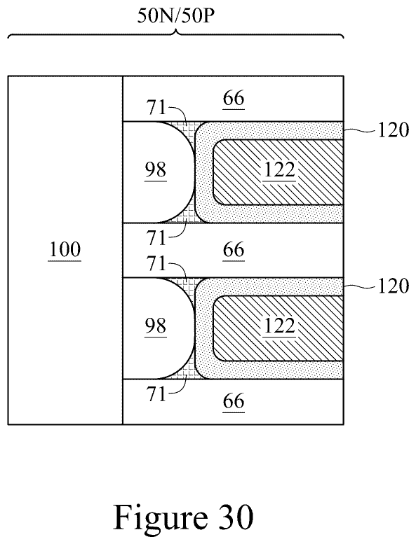

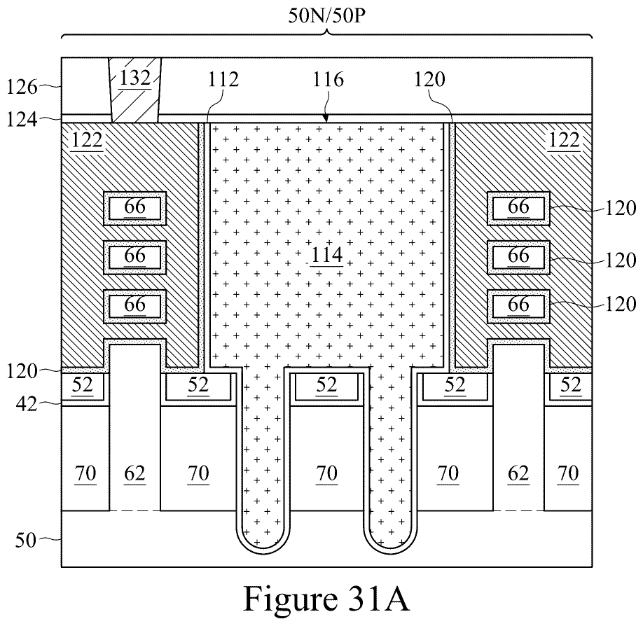

In FIGS. 21A-21C, an etching mask 108 is formed over the hard mask layer 106 and patterned, in accordance with some embodiments. The etching mask 108 may be a photoresist, a photoresist structure, or the like, and may be formed of a single layer or of multiple layers. For example, the etching mask 108 may be a bi-layer structure or a tri-layer structure comprising a bottom anti-reflection coating (BARC) and/or a photoresist layer, in some embodiments. The etching mask 108 may be patterned using suitable photolithography techniques to form openings 110 that expose the underlying hard mask layer 106. The openings 110 correspond to the pattern of the subsequently formed transistor isolation regions 116. Accordingly, the openings 110 may extend over regions of the dummy gates 84 that are subsequently replaced by the transistor isolation regions 116. FIG. 21A shows the opening 110 extending across two fins 62, but in other embodiments an opening 110 may extend across only one fin 62 or may extend across more than two fins 62. The openings 110 may have oblique or tapered sidewalls (as illustrated) or may have approximately vertical sidewalls.

In FIGS. 22A-22C, one or more etching processes are performed to extend the openings 110 into the underlying regions of the dummy gates 84, in accordance with some embodiments. In some embodiments, the openings 110 in the etching mask 108 are first transferred to the hard mask layer 106 using one or more etching steps. The etching steps may include a suitable anisotropic etching process. In this manner, the hard mask layer 106 may be patterned, with the pattern corresponding to the subsequently formed transistor isolation regions 116. The openings 110 in the hard mask layer 106 exposes regions of the dummy gates 84, in some embodiments. After the hard mask layer 106 has been patterned, the etching mask 108 may be removed using a suitable process, such as an etching process, a planarization process (e.g., a CMP or grinding process), a combination thereof, or the like.

The openings 110 in the hard mask layer 106 are then transferred into the dummy gates 84 using one or more etching processes, in accordance with some embodiments. The etching processes may include, for example, a dry etching process that selectively etches the material of the dummy gates 84 at a faster rate than the materials of the hard mask layer 106, the gate spacers 92, the dielectric liner 42, and the hard mask 52. In this manner, the exposed regions of the dummy gates 84 may be removed without substantial etching of other layers or materials of the structure. In some cases, the dielectric liner 42 acts as an etch stop layer that protects the nanostructures 66 and the fins 62 from the etching. In other embodiments, the etching processes may thin or remove regions of the hard mask 52 that are exposed by removal of the dummy gate 84 regions. After the etching, the exposed sidewalls of the dummy gates 84 may be substantially vertical (as illustrated), tapered, concave, and/or convex.

In FIGS. 23A-23C, the dielectric liner 42 and the dummy regions 72 in the opening 110 are removed, in accordance with some embodiments. Removing the dielectric liner 42 and dummy regions 72 exposes the nanostructures 66 that were previously surrounded by the removed regions of dummy gates 84. Inner spacers 98 and upper surfaces (e.g., top surfaces and/or sidewall surfaces) of the fins 62 may also be exposed. In some embodiments, removing the dielectric liner 42 and the dummy regions 72 may include performing an isotropic etching process such as a wet etching process or the like. The etching process may use etchants which are selective to the materials of the dielectric liner 42 and the dummy regions 72, while the nanostructures 66, the fins 62, the inner spacers 98, and the hard mask 52 remain relatively unetched. Other etching processes are possible.

By forming a hard mask 52 over the STI regions 70 as described herein, the STI regions 70 are protected from etching during removal of the dummy regions 72. In this manner, the dummy regions 72 can be removed without etching the STI regions 70, which can minimize the risk of defects due to the STI regions 70 being etched or damaged. For example, without the presence of the hard mask 52, the isotropic etch used to remove the dummy regions 72 may laterally etch portions of the STI regions 70, and may remove portions of the STI regions 70 near fins 62 that are not within the opening 110. Removing STI regions 70 outside of the opening 110 can increase the risk of several problems, such as increased parasitic capacitance, fin 62 damage during subsequent etching processes, or the formation of parasitic transistors that can degrade device performance. Accordingly, blocking the isotropic etch using a hard mask 52 can reduce the risk of defects, damage, or reduced device performance due to etching of the STI region 70. Additionally, the use of a dielectric liner 42 as described herein allows regions of the dummy gates 84 to be selectively etched in a separate etch step before subsequent etching of the nanostructures 66 and fins 62 (see FIGS. 24A-24C). Removing the dummy gates 84 in a separate selective etch step can allow for reduced etching of the hard mask 52 and more complete and uniform etching of the nanostructures 66 and fins 62, described in greater detail below.

In FIGS. 24A-24C, an etching process is performed to etch the nanostructures 66 and fins 62 in the opening 110, in accordance with some embodiments. The etching process removes the exposed nanostructures 66 within the opening 110 and etches the exposed fins 62 within the opening 110. The etching process may be, for example, an anisotropic dry etching process that selectively etches the nanostructures 66, the fins 62, and the substrate 50, described in greater detail below. The etching of the fins 62 extends the opening 110 through the STI region 70 and may extend the opening 110 into the substrate 50, as shown in FIGS. 24A-24B. The exposed portions of the fins 62 may be completely removed by the etching process. Each etched fin 62 forms a separate extension of the opening 110 into the substrate 50. For example, the two fins 62 exposed by the opening 110 (e.g., as shown in FIG. 23A) are etched to form two corresponding extensions 110-1 and 110-2 of the opening 110 into the substrate 50, as shown in FIG. 24A. The hard mask 52 protects the top surfaces of the STI regions 70 from the etching process such that the extensions 110-1 and 110-2 are separated by a region of hard mask 52 and a portion of the STI region 70 underneath the region of hard mask 52. The use of a hard mask 52 over the STI regions 70 as described herein thus allows for improved control of the etching of the fins 62 with less STI region 70 loss during etching. This can allow for improved etching uniformity and reproducibility, and reduced chance of defects or damage.

In some embodiments, the anisotropic etching process used to remove the nanostructures 66 and/or fins 62 is a plasma dry etching process. In some embodiments, the etching process may be performed using a gas source comprising HBr or the like. In some embodiments, during the etching process, other gases, such as Cl₂, BCl₃, O₂, CO₂, the like, or a combination thereof, may be added to the gas source to adjust various aspects of the etching process, such as etching rate, etching selectivity (e.g., selectivity between silicon and silicon oxide), and/or etching profile.

During the etching process, the gas source is ignited into plasma by a plasma etching tool. The plasma etching tools may use an Inductively Coupled Plasma (ICP)/dipole antenna, though other types of plasma tools may be used. In some embodiments, a Radio Frequency (RF) power generator of the plasma etching tool generates a RF power source (e.g., a RF signal) at 13.56 MHz or 27 MHz. The etching process may be performed at a pressure in the range of about 3 mTorr to about 150 mTorr, and at a temperature in the range of about 20° C. to about 200° C. A power of the RF power source may be in the range of about 100 W to about 2500 W. In some embodiments, the etching process uses a pulsed plasma etch technique, in which a duty cycle of the RF power source is between about 5% and 100%. In some embodiments, the etching process comprises a RF bias power in the range of about 10 W to about 1200 W. Other process parameters are possible.

In some embodiments, in order to protect the hard mask 52 and to preserve the dimensions of the opening 110 during the etching process, a passivation layer is formed (e.g., conformally) over the upper surface of the hard mask 52 and along the sidewalls and the bottom of the opening 110. The passivation layer may also be formed over surfaces of the nanostructures 66 during removal of the nanostructures 66 and/or surfaces of the fins 62 during removal of the fins 62. The passivation layer may be, for example, a carbon-based passivation layer formed by injecting CH₄ into the plasma etching tool during the etching process. A carrier gas, such as Ar or N₂, may be used to carry CH₄ into the plasma etching tool. In some embodiments, the passivation layer is a SiO-based passivation layer formed by injecting SiCl₄ and O₂ gases (e.g., simultaneously or sequentially) into the plasma etching tool during the etching process. A carrier gas, such as Ar or N₂, may be used to carry SiCl₄ and O₂ into the plasma etching tool. In some embodiments, additional chemicals, such as HBr or the like, are injected into the plasma etching tool chamber along with SiCl₄ to facilitate the dissociation of SiCl₄ in the SiO-based passivation layer formation process. The bromine generated by the chemical reaction may further react with SiO₂ to form SiBrO. Therefore, the composition of the SiO-based passivation layer may include SiBrO, in some cases.

After the passivation layer is formed, a break-through etching step is performed to remove the passivation layer from the etch front (e.g., remove the passivation layer from surfaces of the nanostructures 66, from surfaces of the fin 62, and/or from the bottom of the opening 110), such that subsequent etching steps can be performed to remove the nanostructures 66 and/or the fins 62. In some embodiments, the break-through etching step is an anisotropic etching process (e.g., a plasma etching process) performed using a gas source comprising CF₄, CHF₃, CH₂F₂, C₄F₆, the like, or a combination thereof. After the break-through etching step, the passivation layer at the bottom of the opening 110 is removed, while the sidewalls of the opening 110 may remain covered by the passivation layer.

In some embodiments, the etching process to remove the nanostructures 66 and/or the fins 62 in the opening 110 includes multiple etching cycles, in which each of the multiple etching cycles includes the following three sequential processing steps: 1) forming a passivation layer (e.g., a carbon-based or SiO-based passivation layer) on the hard mask 52 and along the sidewalls and the bottom of the opening 110; 2) performing the break-through etching step to remove the passivation layer from the etch front; and 3) performing the etching process to remove the nanostructures 66 and/or fins 62.

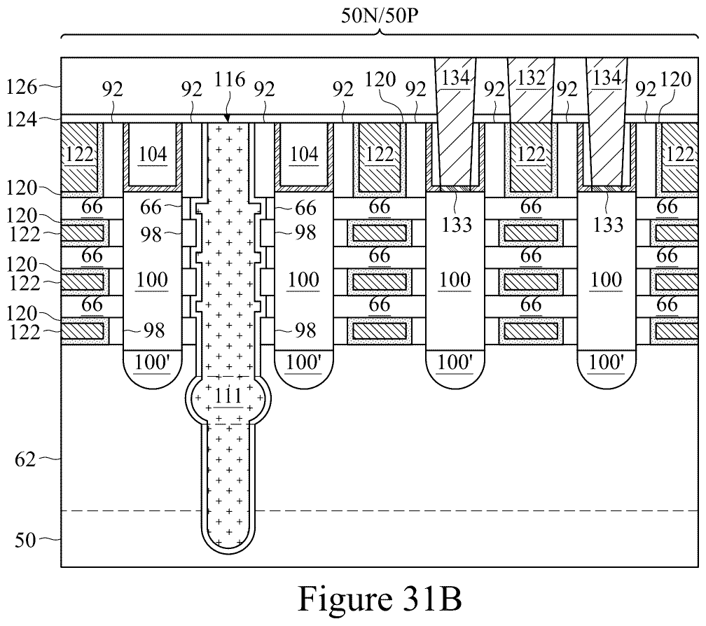

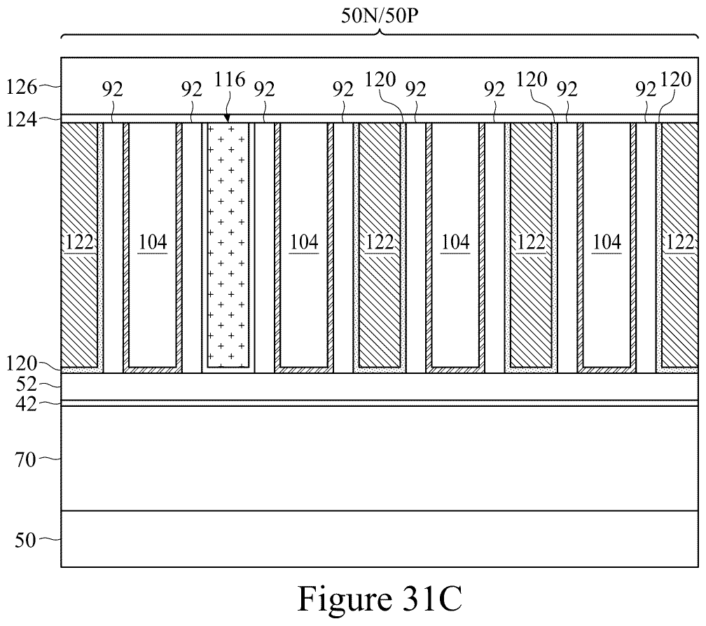

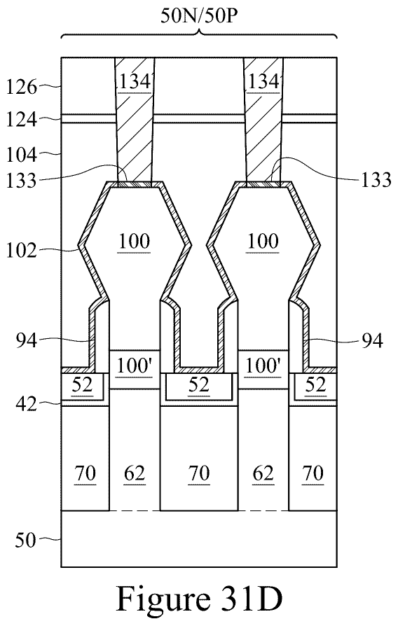

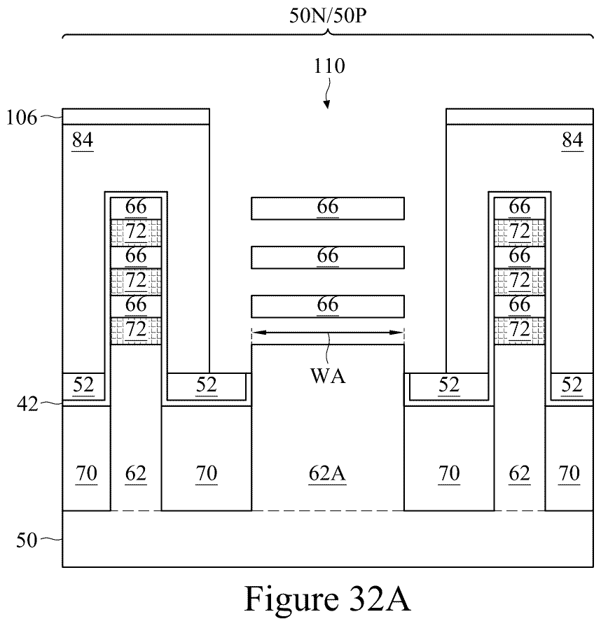

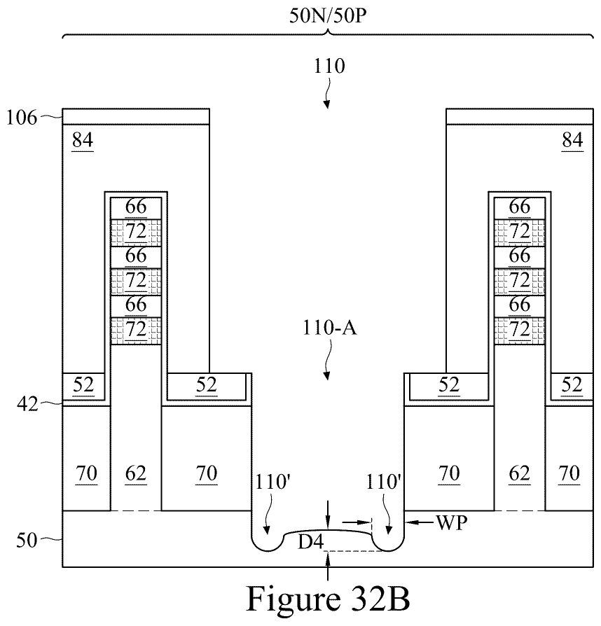

In some embodiments, the depth D1 of an opening 110 measured from a top surface of the nanostructures 66 is in the range of about 140 nm to about 250 nm, though other depths D1 are possible. In some embodiments, a bottom surface of the opening 110 is at or below a bottom surface of the STI regions 70. In some embodiments, the etching process thins the hard mask 52 regions exposed in the opening. For example, after performing the etching process, exposed regions of the hard mask 52 may have a thickness T2 that is less than the thickness T1 (see FIG. 8C) of the unetched hard mask 52. For example, the thickness T2 may be in the range of about 1 nm to about 10 nm. Other thicknesses are possible. After etching, exposed regions of the hard mask 52 may have top surfaces that are flat, convex, and/or concave. In some cases, center portions of the hard mask 52 may have a thickness T2 that is greater than a thickness T2 at sidewalls of the hard mask 52. Some additional characteristics of the openings formed by the etching process are described below for FIGS. 32A-34B.

In some cases, the geometry of the opening 110 may form wider regions 111 of the opening 110 within a fin 62 during the etching process. The extensions of the opening 110 below the hard mask 52 (e.g., extensions 110-1 or 110-2) are narrower than the opening 110 above the hard mask 52. This narrowing of the opening 110 as the fin 62 is etched below the hard mask 52 may increase etchant flux density and/or increase etchant pressure in regions of the opening 110 below and near a top surface of the hard mask 52. In some cases, the wider regions 111 are formed near top surfaces of the STI regions 70. The increased etchant density and/or pressure may cause more etching of the fin 62 in these regions, forming the wider regions 111. An example wider region 111 of an opening 110 is shown in FIG. 24B. The wider regions 111 are regions of the opening 110 within a fin 62 that are relatively wider than regions of the opening 110 above and below the wider region 111. The relatively larger width of a wider region 111 may be measured along the longitudinal direction of the fin 62.

In some embodiments, a width W1 between opposite nanostructures 66 at sidewalls of the opening 110 may be in the range of about 17 nm to about 23 nm. In some embodiments, a wider region 111 may have a width W2 that is in the range of about 25 nm and about 35 nm. The width W2 may be between about 110% and about 220% of a width W1. In some embodiments, the largest width W2 of a wider region 111 may be a distance D2 from a top surface of the nanostructures 66 that is in the range of about 60 nm to about 75 nm. In some embodiments, a wider region 111 may have a vertical span D3 that is in the range of about 40 nm to about 70 nm. Other distances, shapes, locations, sizes, or dimensions are possible. In some embodiments, the top of the wider region 111 may be at or near a top surface of the hard mask 52. In other embodiments, the top of the wider region 111 may be above (e.g., farther from the substrate 50 than) the hard mask 52 or below (e.g., closer to the substrate 50 than) the hard mask 52. In some embodiments, a wider region 111 may extend under an epitaxial source/drain region 100 or extend into the substrate 50. The size and location of the wider regions 111 may be controlled, for example, by controlling the thickness of various layers such as the hard mask 52, STI regions 70, or the fins 62, or may be controlled by controlling etching parameters. In some embodiments, no wider regions 111 are formed.

In FIGS. 25A-25C, a liner layer 112 and a dielectric fill 114 are deposited in the openings 110, in accordance with some embodiments. The liner layer 112 and dielectric fill 114 are deposited as part of forming the transistor isolation regions 116, described below. In some embodiments, the liner layer 112 is conformally deposited on surfaces in the opening 110, including on surfaces of the dummy gates 84, hard mask 52, STI regions 70, fins 62, and substrate 50 that were exposed by the opening 110. The liner layer 112 may also be deposited on other surfaces in the opening 110, such as surfaces of the gate spacers 92, inner spacers 98, and nanostructures 66. In some embodiments, the liner layer 112 is also deposited over top surfaces and sidewalls of the hard mask layer 106. The dielectric fill 114 is then deposited on the liner layer 112, filling the opening 110. The materials of the liner layer 112 and the dielectric fill 114 may be selected from suitable dielectric materials, such as silicon oxide, silicon nitride, silicon oxynitride, silicon oxycarbonitride, silicon carbonitride, the like, or combinations thereof. For example, in some embodiments, the liner layer 112 comprises silicon oxide and the dielectric fill 114 comprises silicon nitride. Other materials or combinations of materials are possible. The liner layer 112 and the dielectric fill 114 may be formed using suitable techniques, such as CVD, PECVD, ALD, or the like. In other embodiments, the liner layer 112 is omitted. In other embodiments, additional dielectric layers may be deposited on the liner layer 112 and/or the dielectric fill 114 as part of forming the transistor isolation regions 116.

In FIGS. 26A-26C, a planarization process is performed to remove excess liner layer 112 and dielectric fill 114 and form the transistor isolation regions 116, in accordance with some embodiments. The planarization process may include a CMP process, a grinding process, or the like. In some embodiments, the planarization process removes the hard mask layer 106 and the liner layer 112 and the dielectric fill 114 over the hard mask layer 106. The remaining portions of the liner layer 112 and the dielectric fill 114 form the transistor isolation regions 116. In some embodiments, after performing the planarization process, top surfaces of the transistor isolation regions 116, dummy gates 84, gate spacers 92, and first ILD 104 are substantially level or coplanar. In embodiments in which a capping layer (described previously for FIGS. 19A-19D) is formed over the first ILD 104, the planarization process may expose top surfaces of the capping layer or may remove the capping layer. In some cases, because the wider regions 111 laterally extend near the epitaxial source/drain regions 100, the dielectric materials of the transistor isolation regions 116 within the wider regions 111 can reduce parasitic capacitances of the nearby epitaxial source/drain regions 100. In this manner, forming wider regions 111 of the transistor isolation regions 116 can improve device performance.

In FIGS. 27A-27C, the dummy gates 84 are removed in one or more etching steps, in accordance with some embodiments. Removing the dummy gates 84 forms recesses 118 between the gate spacers 92. In some embodiments, the dummy gates 84 are removed by an anisotropic dry etching process. For example, the etching process may include a dry etch process using reaction gas(es) that selectively etch the material of the dummy gates 84 at a faster rate than the materials of the first ILD 104, the gate spacers 92, and the transistor isolation regions 116. In other embodiments, a selective wet etching process may be used to remove the dummy gates 84. During the removal, the dielectric liner 42 and/or the hard mask 52 may be used as an etch stop layers when the dummy gates 84 are etched.

In FIGS. 28A-28C, the dummy regions 72 are removed, extending the recesses 118, in accordance with some embodiments. In some embodiments, the exposed regions of the dielectric liner 42 are also removed along with the dummy regions 72. Removing the dielectric liner 42 and the dummy regions 72 may include an isotropic wet etching process or the like. The etching process may use etchants which are selective to the materials of the dielectric liner 42 and the dummy regions 72, while the nanostructures 66 remain relatively unetched. The hard mask 52 protects the STI regions 70 from the etching process. The capping layer (if present) may protect the first ILD 104 from the etching process.

The dummy material 71 of the dummy regions 72 may be completely removed, or a residue of the dummy material 71 may remain on some sidewall portions of the inner spacers 98 in the recesses 118 (see e.g., FIG. 30). After removing the dummy regions 72, each recess 108 exposes portions of nanostructures 66, which act as channel regions in subsequently completed nanostructure-FETs. Portions of the nanostructures 66 which act as the channel regions are disposed between neighboring pairs of the epitaxial source/drain regions 100.

In FIGS. 29A-29C, gate dielectric layers 120 and gate electrodes 122 are formed for replacement gate structures, in accordance with some embodiments. The gate dielectric layers 120 are deposited conformally in the recesses 118. The gate dielectric layers 120 may be formed on top surfaces and sidewalls of the substrate 50 and on exposed top surfaces, sidewalls, and bottom surfaces of the nanostructures 66. The gate dielectric layers 120 may also be deposited on top surfaces of the first ILD 104, the CESL 102, the gate spacers 92, and/or the STI regions 70. Because the transistor isolation regions 116 are formed before the gate structures, the gate dielectric layers 120 are deposited on sidewalls of the transistor isolation regions 116. For example, the gate dielectric layers 120 may be deposited along the liner layer 112 at sidewalls of the transistor isolation regions 116, as shown in FIG. 29A.

In accordance with some embodiments, the gate dielectric layers 120 comprise one or more dielectric layers, such as layer(s) of oxide, metal oxide, the like, or combinations thereof. For example, in some embodiments, the gate dielectric layers 120 may comprise a silicon oxide layer and a metal oxide layer over the silicon oxide layer. In some embodiments, the gate dielectric layers 120 include a high-k dielectric material, and in these embodiments, the gate dielectric layers 120 may have a k value greater than about 7.0, and may include a metal oxide or a silicate of hafnium, aluminum, zirconium, lanthanum, manganese, barium, titanium, lead, and combinations thereof. The structure of the gate dielectric layers 120 may be the same or different in the n-type region 50N and the p-type region 50P. The formation methods of the gate dielectric layers 120 may include molecular-beam deposition (MBD), ALD, PECVD, and the like.

The gate electrodes 122 are deposited over the gate dielectric layers 120, respectively, and fill the remaining portions of the recesses 118. The gate electrodes 122 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 122 are illustrated in FIGS. 29A and 29B, the gate electrodes 122 may comprise any number of liner layers, any number of work function tuning layers, and a fill material. Any combination of the layers which make up the gate electrodes 122 may be deposited over surfaces of the nanostructures 66.

The formation of the gate dielectric layers 120 in the n-type region 50N and the p-type region 50P may occur simultaneously such that the gate dielectric layers 120 in each region are formed from the same materials, and the formation of the gate electrodes 122 may occur simultaneously such that the gate electrodes 122 in each region are formed from the same materials. In some embodiments, the gate dielectric layers 120 in each region may be formed by distinct processes, such that the gate dielectric layers 120 may be different materials and/or have a different number of layers, and/or the gate electrodes 122 in each region may be formed by distinct processes, such that the gate electrodes 122 may be different materials and/or have a different number of layers. Various masking steps may be used to mask and expose appropriate regions when using distinct processes.

After the filling of the recesses 118, a planarization process, such as a CMP process, may be performed to remove the excess portions of the gate dielectric layers 120 and the material of the gate electrodes 122, which excess portions are over the top surface of the first ILD 104. The remaining portions of material of the gate electrodes 122 and the gate dielectric layers 120 thus form replacement gate structures of the resulting nanostructure-FETs. The gate electrodes 122 and the gate dielectric layers 120 may be collectively referred to as gate structures or gate stacks. The transistor isolation regions 116 separate and isolate regions of the gate structures, as shown in FIG. 29A.

FIG. 30 illustrates a detailed view of various elements of FIG. 29B, including the epitaxial source/drain regions 100, the gate dielectric layers 120, the gate electrodes 122, the nanostructures 66, and the inner spacers 98. The view of FIG. 30 may be a magnified view of a portion of a nanostructure-FET in the n-type region 50N or the p-type region 50P, and may be similar to the region 30 indicated in FIG. 29B. In some embodiments, illustrated by FIG. 30, a residue of the dummy material 71 may remain on the inner spacers 98, such as between the inner spacers 98 and the gate dielectric layers 120. For example, the dummy regions 72 may not be fully removed, and the gate dielectric layers 120 may be formed on the remaining dummy material 71 of the dummy regions 72. Because the dummy material 71 is an insulating material (e.g., silicon oxide or the like), the remaining residue may not significantly impact the electrical performance of the resulting device.

In FIGS. 31A-31D, a second ILD 126 is deposited over the gate spacers 92, the CESL 102, the first ILD 104, and the gate structures, in accordance with some embodiments. In some embodiments, the second ILD 126 is a flowable film formed by a flowable CVD method. In some embodiments, the second ILD 126 is formed of a dielectric material such as PSG, BSG, BPSG, USG, or the like, which may be formed by any suitable deposition process, such as CVD, PECVD, or the like.

In some embodiments, an etch stop layer (ESL) 124 is formed before deposition of the second ILD 126. The ESL 124 may be formed of a dielectric material having a high etching selectivity from the etching of the second ILD 126 such as silicon nitride, silicon oxide, silicon oxynitride, or the like, which may be formed by any suitable deposition process, such as CVD, ALD, or the like.

In other embodiments, the gate structures (including the gate dielectric layers 120 and the corresponding overlying gate electrodes 122) are recessed, so that recesses (not separately illustrated) are formed directly over the gate structures between opposing portions of gate spacers 92. A gate mask (not separately illustrated) comprising one or more layers of dielectric material, such as silicon nitride, silicon oxynitride, or the like, may be filled in the recesses, followed by a planarization process to remove excess portions of the dielectric material. Subsequently formed gate contacts (such as the gate contacts 132, discussed below) penetrate through the gate mask to contact the top surfaces of the recessed gate electrodes 122.

Further in FIGS. 31A-31D, gate contacts 132 and source/drain contacts 134 are formed to contact, respectively, the gate electrodes 122 and the epitaxial source/drain regions 100. The gate contacts 132 may be physically and electrically coupled to the gate electrodes 122. The source/drain contacts 134 may be physically and electrically coupled to the epitaxial source/drain regions 100.

As an example of forming the gate contacts 132 and the source/drain contacts 134, openings for the gate contacts 132 are formed through the second ILD 126 and the ESL 124, and openings for the source/drain contacts 134 are formed through the second ILD 126, the ESL 124, the first ILD 104, the CESL 102, and the capping layer (if present). The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 126. The remaining liner and conductive material form the gate contacts 132 and the source/drain contacts 134 in the openings. The gate contacts 132 and the source/drain contacts 134 may be formed in distinct processes, or may be formed in the same process. Although shown as being formed in the same cross-sections, it should be appreciated that each of the gate contacts 132 and the source/drain contacts 134 may be formed in different cross-sections, which may avoid shorting of the contacts.

Optionally, metal-semiconductor alloy regions 133 are formed at the interfaces between the epitaxial source/drain regions 100 and the source/drain contacts 134. The metal-semiconductor alloy regions 133 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 133 can be formed before the material(s) of the source/drain contacts 134 by depositing a metal in the openings for the source/drain contacts 134 and then performing a thermal annealing process. The metal can be any metal capable of reacting with the semiconductor materials (e.g., silicon, silicon carbide, silicon germanium, germanium, etc.) of the epitaxial source/drain regions 100 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 134, such as from surfaces of the metal-semiconductor alloy regions 133. The material(s) of the source/drain contacts 134 can then be formed on the metal-semiconductor alloy regions 133.

In some cases, the etching process to remove nanostructures 66 and fins 62 in the opening 110, described previously for FIGS. 24A-24C, can produce different characteristics depending on the width of the fins 62. Some examples are described below for FIGS. 32A-34B. FIGS. 32A, 33A, and 34A illustrate cross-sectional views prior to etching of the nanostructures 66 and fin 62, similar to FIG. 23A. FIGS. 32B, 33B, and 34B illustrate cross-sectional views after etching of the nanostructures 66 and fin 62, similar to FIG. 24A. In each of FIGS. 32A, 33A, and 34A, only one fin 62 is exposed by the opening 110 and etched, respectively referred to as fin 62A, fin 62B, and fin 62C. The fins 62A-C are similar to other fins 62 described herein. The nanostructures 66, fins 62, and etching thereof in FIGS. 32A-34B are intended as illustrative examples, and other configurations, dimensions, or etching results are possible.

FIGS. 32A and 32B illustrate the etching of a fin 62A, in accordance with some embodiments. The fin 62A may have a width WA that is about 60 nm or greater, for example. The nanostructures 66 over the fin 62A have a width correspondingly similar to the width WA. FIG. 32B illustrates the structure after the fin 62A is removed using an etching process similar to that described for FIG. 24A. As shown in FIG. 32B, removing the fin 62A forms an extension 110-A of the opening 110 into the substrate 50. The extension 110-A may have a width approximately the same as the width WA, in some cases. The liner layer 112 and dielectric fill 114 may be deposited in the opening 110 to form a transistor isolation region 116, similar to the process described for FIGS. 25A-26C.

Notably, the extension 110-A includes two protruding regions 110′ at the bottom corners of the extension 110-A. The protruding regions 110′ are notched regions near the sidewalls (e.g., the edges) of the extension 110-A that extend deeper than regions away from the sidewalls of the extension 110-A. The protruding regions 110′ may be formed, for example, by the etching process etching the sides of the nanostructures 66 and fin 62A at faster rate than the center regions of the nanostructures 66 and fin 62A. In some embodiments, the protruding regions 110′ may have a depth D4 that is in the range of about 3 nm to about 15 nm, or a width WP that is in the range of about 15 nm to about 35 nm. Other depths, widths or other dimensions are possible, and the dimensions of the protruding regions 110′ may depend on the width WA of the fin 62 (e.g. fin 62A). For example, in some cases, the depth and/or width of the protruding regions 110′ may be larger for larger fin 62 width (e.g., larger width WA). In some embodiments, the dimensions of the protruding regions 110′ may be controlled by controlling the etching process parameters. Accordingly, the subsequently formed transistor isolation region 116 may include protruding portions corresponding to the protruding regions 110′. In some cases, the protruding regions 110′ are not formed. In some cases, removing the dummy gates 84 in a separate selective etching step before removing the nanostructures 66 and fins 62, as described herein, can allow for more uniform, consistent, and complete removal of the fins 62. This can allow for more uniform and reproducible subsequent formation of transistor isolation regions 116, which can improve the isolation provided by the transistor isolation regions 116.

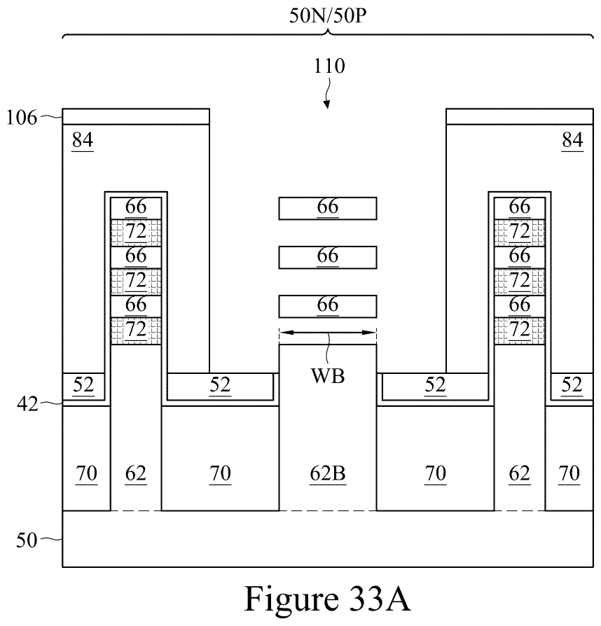

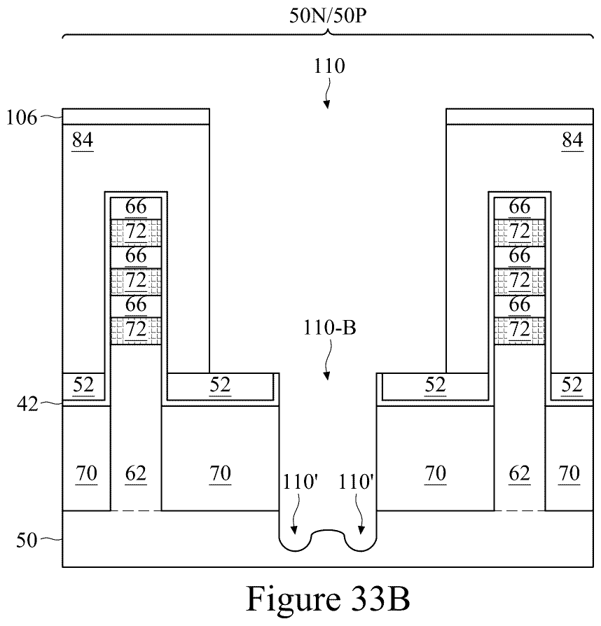

FIGS. 33A and 33B illustrate the etching of a fin 62B having a width WB that is less than the width WA of fin 62A, in accordance with some embodiments. The fin 62B may have a width WB that is in the range of about 20 nm to about 60 nm, for example. The nanostructures 66 over the fin 62B have a width correspondingly similar to the width WB. FIG. 33B illustrates the structure after the fin 62B is removed using an etching process similar to that described for FIG. 24A. As shown in FIG. 33B, removing the fin 62B forms an extension 110-B of the opening 110 into the substrate 50. The extension 110-B may have a width approximately the same as the width WB, in some cases. Similar to the extension 110-A, protruding regions 110′ may be formed in the extension 110-B. In FIGS. 33A-33B, the width WB of the fin 62B is large enough that the resulting protruding regions 110′ are separated by a raised region. The liner layer 112 and dielectric fill 114 may be deposited in the opening 110 to form a transistor isolation region 116, similar to the process described for FIGS. 25A-26C.

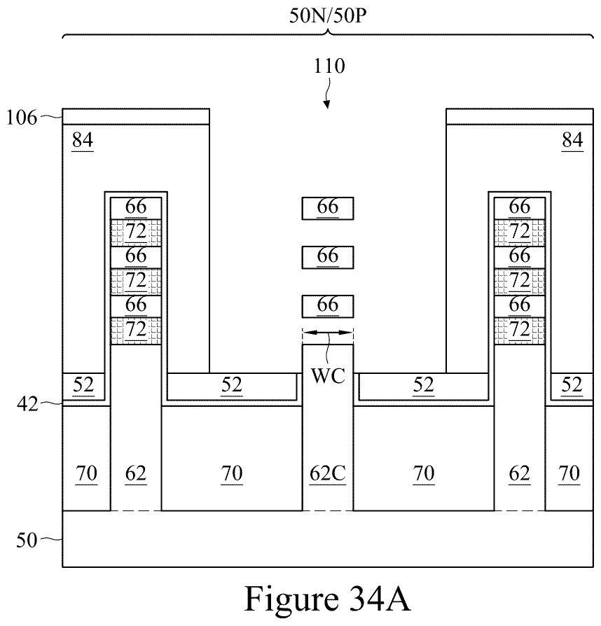

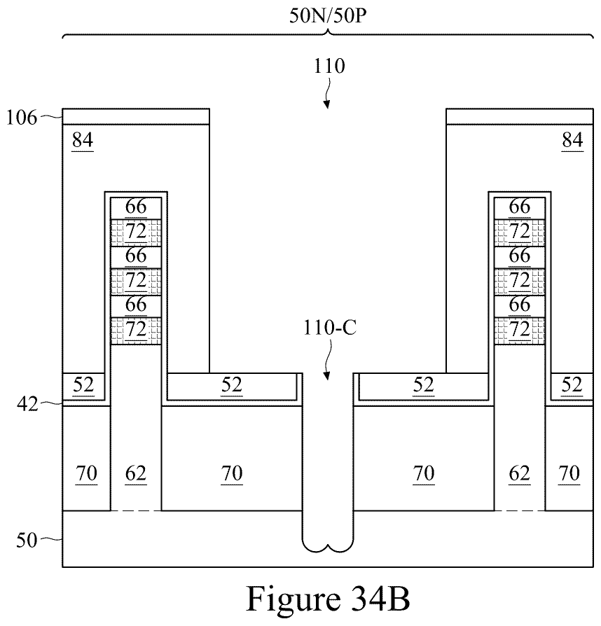

FIGS. 34A and 34B illustrate the etching of a fin 62C having a width WC that is less than the width WB of fin 62B, in accordance with some embodiments. The fin 62C may have a width WC that is about 20 nm or less, for example. The nanostructures 66 over the fin 62C have a width correspondingly similar to the width WC. FIG. 34B illustrates the structure after the fin 62C is removed using an etching process similar to that described for FIG. 24A. As shown in FIG. 34B, removing the fin 62B forms an extension 110-C of the opening 110 into the substrate 50. The extension 110-C may have a width approximately the same as the width WC, in some cases. In FIGS. 34A-34B, the width WC of the fin 62C is small enough that the resulting protruding regions 110′ overlap and may not be distinguishable. In some cases, a small raised region may be present near the center of the extension 110-C. The liner layer 112 and dielectric fill 114 may be deposited in the opening 110 to form a transistor isolation region 116, similar to the process described for FIGS. 25A-26C.

Embodiments may achieve advantages. The techniques described herein allow for improved formation of transistor isolation regions with reduced risk of defects or damage. By forming a hard mask over STI regions, the STI regions may be protected from undesired etching during formation of the transistor isolation regions. This can reduce the risk of etch damage to nearby fins. Additionally, reducing the etching of the STI regions near fins can reduce the formation of parasitic transistors after the dielectric material of the transistor isolation regions is deposited. In this manner, yield and device performance may be improved. Additionally, the use of multiple selective etches to remove dummy gates, dummy regions, nanostructures, and fins can allow for more uniform and complete removal during formation of the transistor isolation regions.

In an embodiment, a method includes forming a fin over a substrate; forming a first isolation region over the substrate; forming a hard mask over the first isolation region, wherein the fin protrudes from the hard mask; forming dummy nanostructures over the fin; removing the dummy nanostructures; removing a portion of the fin to form an opening extending through the hard mask and the first isolation region; forming a second isolation region over the hard mask and in the opening; and forming a gate structure along a sidewall of the second isolation region. In an embodiment, the first isolation region is an oxide and the hard mask is a nitride. In an embodiment, the method includes forming first nanostructures over the fin, wherein removing the portion of the fin removes the first nanostructures. In an embodiment, forming the dummy nanostructures over the fin includes: forming second nanostructures over the fin; and replacing the second nanostructures with dielectric regions. In an embodiment, removing the dummy nanostructures includes performing an isotropic wet etching process. In an embodiment, the method includes forming a dummy gate over the hard mask, the dummy nanostructures, and the fin. In an embodiment, the second isolation region extends on a top surface of the hard mask. In an embodiment, forming the hard mask includes: depositing a hard mask material over the first isolation region and the fin; and removing upper portions of the hard mask material.

In an embodiment, a method includes forming a first fin over a substrate; forming first nanostructures and second nanostructures over the first fin; forming an isolation region surrounding the first fin; forming a protective layer over the isolation region; forming a dummy gate over the protective layer, the first fin, the first nanostructures, and the second nanostructures; performing a first selective etching process to form an opening in the dummy gate over the first fin; performing a second selective etching process in the opening to remove the second nanostructures; performing a third selective etching process in the opening to remove the first nanostructures and the first fin; and filling the opening with an insulating material. In an embodiment, the method includes, before forming the protective layer, depositing a dielectric liner over the isolation region, the first fin, the first nanostructures, and the second nanostructures. In an embodiment, the dielectric liner includes silicon oxide. In an embodiment, the first selective etching process selectively etches the material of the dummy gate from the material of the protective layer. In an embodiment, the second selective etching process selectively etches the material of the second nanostructures over the material of the protective layer. In an embodiment, the second selective etching process thins the protective layer. In an embodiment, the second nanostructures include silicon oxide.

In an embodiment, a device includes a first fin and a second fin over a substrate; an isolation region surrounding the first fin and the second fin; a hard mask over the isolation region and surrounding the first fin and the second fin; nanostructures over the first fin; an isolation structure extending on the hard mask and extending through the second fin to the substrate; and a gate structure on the hard mask, the first fin, the nanostructures, and a first sidewall of the isolation structure. In an embodiment, the widest portion of the isolation structure is below a top surface of the second fin. In an embodiment, the isolation structure is separated from the first fin by the isolation region. In an embodiment, the isolation region and the hard mask are different dielectric materials. In an embodiment, a first portion of the isolation structure near a second sidewall of the isolation structure protrudes into the substrate more than a second portion of the isolation structure away from the second sidewall of the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a fin over a substrate;
forming a first isolation region over the substrate;
forming a hard mask over the first isolation region, wherein the fin protrudes from the hard mask;
forming a plurality of dummy nanostructures over the fin;
removing the plurality of dummy nanostructures;
removing a portion of the fin to form an opening extending through the hard mask and the first isolation region;
forming a second isolation region over the hard mask and in the opening; and
forming a gate structure along a sidewall of the second isolation region.

2. The method of claim 1, wherein the first isolation region is an oxide and the hard mask is a nitride.

3. The method of claim 1 further comprising forming a plurality of first nanostructures over the fin, wherein removing the portion of the fin removes the plurality of first nanostructures.

4. The method of claim 1, wherein forming the plurality of dummy nanostructures over the fin comprises:
forming a plurality of second nanostructures over the fin; and
replacing the plurality of second nanostructures with a plurality of dielectric regions.

5. The method of claim 1, wherein removing the plurality of dummy nanostructures comprises performing an isotropic wet etching process.

6. The method of claim 1 further comprising forming a dummy gate over the hard mask, the plurality of dummy nanostructures, and the fin.

7. The method of claim 1, wherein the second isolation region extends on a top surface of the hard mask.

8. The method of claim 1, wherein forming the hard mask comprises:
depositing a hard mask material over the first isolation region and the fin; and
removing upper portions of the hard mask material.

9. A method comprising:
forming a first fin over a substrate;
forming a plurality of first nanostructures and a plurality of second nanostructures over the first fin;
forming an isolation region surrounding the first fin;
forming a protective layer over the isolation region;
forming a dummy gate over the protective layer, the first fin, the plurality of first nanostructures, and the plurality of second nanostructures;
performing a first selective etching process to form an opening in the dummy gate over the first fin;
performing a second selective etching process in the opening to remove the plurality of second nanostructures;
performing a third selective etching process in the opening to remove the plurality of first nanostructures and the first fin; and
filling the opening with an insulating material.

10. The method of claim 9 further comprising, before forming the protective layer, depositing a dielectric liner over the isolation region, the first fin, the plurality of first nanostructures, and the plurality of second nanostructures.

11. The method of claim 10, wherein the dielectric liner comprises silicon oxide.

12. The method of claim 9, wherein the first selective etching process selectively etches the material of the dummy gate from the material of the protective layer.

13. The method of claim 9, wherein the second selective etching process selectively etches the material of the second nanostructures over the material of the protective layer.

14. The method of claim 9, wherein the second selective etching process thins the protective layer.

15. The method of claim 9, wherein the second nanostructures comprise silicon oxide.

16. A device comprising:
a first fin and a second fin over a substrate;
an isolation region surrounding the first fin and the second fin;
a hard mask over the isolation region and surrounding the first fin and the second fin;
a plurality of nanostructures over the first fin;
an isolation structure extending on the hard mask and extending through the second fin to the substrate; and
a gate structure on the hard mask, the first fin, the plurality of nanostructures, and a first sidewall of the isolation structure.

17. The device of claim 16, wherein the widest portion of the isolation structure is below a top surface of the second fin.

18. The device of claim 16, wherein the isolation structure is separated from the first fin by the isolation region.

19. The device of claim 16, wherein the isolation region and the hard mask are different dielectric materials.

20. The device of claim 16, wherein a first portion of the isolation structure near a second sidewall of the isolation structure protrudes into the substrate more than a second portion of the isolation structure away from the second sidewall of the isolation structure.
